(19) United States
(12) Patent Application Publication
(10) Pub. No.: US 2025/0373202 A1
(43) Pub. Date: Dec. 4, 2025

(54) THERMODYNAMIC COMPUTING RELAY GADGET FOR MULTI-WELL POTENTIALS

(71) Applicant: Extropic Corp., Austin, TX (US)

(72) Inventors: Christopher Chamberland, Austin, TX (US); Guillaume Verdon-Akzam, San Francisco, CA (US)

(73) Assignee: Extropic Corp., Austin, TX (US)

(21) Appl. No.: 18/733,386

(22) Filed: Jun. 4, 2024

(51) Int. Cl. H03B 15/00

(52) U.S. Cl. CPC H03B 15/003

(57) ABSTRACT

A thermodynamic relay gadget includes a set of one or more relay oscillators, an additional relay oscillator, a bias oscillator, and an on-chip controller. Respective ones of the relay oscillators have a time dependent mass or a time dependent frequency that is controllable, by the on-chip controller. The relay gadget is configured to relay thermodynamic information in analog form between an input oscillator of a first energy-based model and an output oscillator of a second energy-based model.

### BACKGROUND

Various algorithms, such as machine learning algorithms, often use statistical probabilities to make decisions or to model systems. Some such learning algorithms may use Bayesian statistics, or may use other statistical models that have a theoretical basis in natural phenomena. Also, machine learning algorithms themselves may be implemented using Bayesian statistics, or may use other statistical models that have a theoretical basis in natural phenomena.

Generating such statistical probabilities may involve performing complex calculations which may require both time and energy to perform, thus increasing a latency of execution of the algorithm and/or negatively impacting energy efficiency. In some scenarios, calculation of such statistical probabilities using classical computing devices may result in non-trivial increases in execution time of algorithms and/or energy usage to execute such algorithms.

As an alternative, algorithms may be performed using thermodynamic computers. However, communication between multiple algorithms implemented on a thermodynamic computing device and/or communications between thermodynamic computing devices may require converting information into a classical computing device form, thus reducing at least some of the benefits of a thermodynamic computer implementation.

### BRIEF DESCRIPTION OF THE DRAWINGS

FIG. 1A is a high-level diagram illustrating an output oscillator, an input oscillator, and a relay gadget, wherein the relay gadget comprises a group of relay oscillators and is configured to relay thermodynamic information between the output oscillator and the input oscillator and includes bias oscillators, according to some embodiments.

FIG. 1B is a high-level diagram illustrating an output oscillator, an input oscillator, and a relay gadget, wherein the relay gadget comprise a group of relay oscillators and is configured to relay thermodynamic information between the output oscillator and the input oscillator, wherein the relay gadget does not include bias oscillators, according to some embodiments.

FIG. 2A is a high-level flowchart illustrating a process of relaying thermodynamic information between an output oscillator and an input oscillator, according to some embodiments.

FIG. 2B is a high-level flowchart illustrating a process of relaying thermodynamic information between an output oscillator and an input oscillator, wherein the process of relaying the thermodynamic information does not require the use of bias oscillators, according to some embodiments.

FIG. 3A is a high-level diagram illustrating a spatial analogue relay gadget, wherein respective ones of relay oscillators of a group of relay oscillators are configured to store respective sample values of an output oscillator, according to some embodiments.

FIG. 3B is high-level diagram similar to FIG. 3A, wherein the relay gadget does not include bias oscillators, according to some embodiments.

FIG. 4 is a high-level flowchart illustrating a process of extracting an expected value of an output oscillator through samples from a plurality of relay oscillators, wherein respective ones of relay oscillators of a group of relay oscillators are configured to store respective sample values of an output oscillator, according to some embodiments.

FIG. 5A is a high-level diagram illustrating a temporal analogue relay gadget, wherein a group of relay oscillators comprises a single relay oscillator, according to some embodiments.

FIG. 5B is high-level diagram similar to FIG. 5A, wherein the relay gadget does not include bias oscillators, according to some embodiments.

FIG. 6 is a high-level flowchart illustrating a process of extracting an expected value of an output oscillator through sampling the output oscillator at several different times, wherein a group of relay oscillators comprises a single relay oscillator, according to some embodiments.

FIG. 7A is a high-level diagram illustrating a series analogue relay gadget, wherein a group of relay oscillators comprises a plurality of relay oscillators arranged in series, according to some embodiments.

FIG. 7B is high-level diagram similar to FIG. 7A, wherein the relay gadget does not include bias oscillators, according to some embodiments.

FIG. 8 is a high-level flowchart illustrating a process of extracting an expected value of an output oscillator through sampling the output oscillator, wherein a group of relay oscillators comprises a plurality of relay oscillators arranged in series, according to some embodiments.

FIG. 9A shows embodiments of possible potentials, according to some embodiments.

FIG. 9B shows embodiments of possible potentials, according to some embodiments.

FIG. 10 is a high-level diagram illustrating forward and backward compatibility, wherein a relay gadget may be used to propagate thermodynamic information forwards and backwards and thus respectively emulate and train a deep neural network using energy-based modules, according to some embodiments.

FIG. 11 is an example of a pulse shape, wherein a coupling coefficient between an output oscillator and an initial relay oscillator is turned on and off three times, to impart three different samples of the output oscillator and the initial relay oscillator, according to some embodiments.

FIG. 12 is a high-level diagram illustrating a spatial analogue relay gadget, wherein respective ones of relay oscillators of a group of relay oscillators are configured to store respective sample values of an output oscillator, wherein the relative size of respective products of mass and frequency squared is represented by a size of respective circles representing an oscillator, wherein the size of respective products of mass and frequency squared can change, according to some embodiments.

FIG. 13 is a high-level diagram illustrating a temporal analogue relay gadget, wherein a group of relay oscillators comprises a single relay oscillator, wherein the relative size of respective products of mass and frequency squared is represented by a size of respective circles representing an oscillator, wherein the size of respective products of mass and frequency squared can change, according to some embodiments.

FIG. 14A is a high-level diagram illustrating a series analogue relay gadget, wherein a group of relay oscillators comprises a plurality of relay oscillators arranged in series, wherein the relative size of respective products of mass and frequency squared is represented by a size of respective circles representing an oscillator, wherein the size of respective products of mass and frequency squared can change, according to some embodiments.

FIG. 14B is a high-level diagram illustrating a series analogue relay gadget, wherein a group of relay oscillators comprises a single relay oscillator arranged in series with an additional relay oscillator, wherein the relative size of respective products of mass and frequency squared is represented by a size of respective circles representing an oscillator, wherein the size of respective products of mass and frequency squared can change, according to some embodiments.

FIG. 14C is a high-level diagram illustrating a series analogue relay gadget, wherein a single relay oscillator is used for forwards and backwards propagation.

FIG. 15A is a diagram illustrating hardware components that may be used to implement oscillators of a first and second energy-based models (EBMs), as well as two different example hardware configurations of a relay oscillator that have a time-dependent mass or a time-dependent frequency, respectively, according to some embodiments.

FIG. 15B is a diagram illustrating hardware components that may be used to implement oscillators of a first and second energy-based models (EBMs), as well as two different example hardware configurations of a relay oscillator that have a time-dependent mass or a time-dependent frequency, respectively, wherein the relay gadget does not include a bias oscillator, according to some embodiments.

FIG. 16 is a diagram providing additional details regarding a hardware configuration used to implement a relay oscillator with a time-dependent frequency, according to some embodiments.

FIG. 17 is a diagram providing additional details regarding a hardware configuration used to implement a relay oscillator with a time-dependent mass, according to some embodiments.

FIG. 18A illustrates example couplings between visible neurons of an energy-based model (EBM), according to some embodiments.

FIG. 18B illustrates example couplings between visible neurons and non-visible neurons (e.g., hidden neurons) of an energy-based model (EBM), according to some embodiments.

FIG. 19 is high-level diagram illustrating a process of determining weights and biases to be used in an energy-based model (EBM), wherein the weights and biases are determined using measurement values for synapse oscillators, according to some embodiments.

FIG. 20 is high-level diagram illustrating a process of determining weights and biases to be used in an energy-based model (EBM), wherein the weights and biases are computed using a classical computing device, according to some embodiments.

FIG. 21 illustrates an example configuration, wherein a first energy-based model (EBM), a second energy-based model (EBM) and a relay gadget are implemented using oscillators of different thermodynamic chips, according to some embodiments.

FIG. 22 illustrates an example configuration, wherein a first energy-based model (EBM), a second energy-based model (EBM) and a relay gadget are implemented using oscillators of a single thermodynamic chip, according to some embodiments.

FIG. 23A is high-level diagram illustrating an example neuro-thermodynamic computer comprising a thermodynamic chip (e.g., that implements multiple energy-based models (EBMs) and a relay gadget) included in a dilution refrigerator and coupled to a classical computing device in an environment external to the dilution refrigerator, according to some embodiments.

FIG. 23B is high-level diagram illustrating an example neuro-thermodynamic computer comprising multiple thermodynamic chips (e.g., that implement respective energy-based models (EBMs) and a relay gadget) included in multiple dilution refrigerators and coupled to a classical computing device in an environment external to the dilution refrigerators, according to some embodiments.

FIG. 24A is high-level diagram illustrating an example neuro-thermodynamic computer comprising a thermodynamic chip (e.g., that implements multiple energy-based models (EBMs) and a relay gadget) included in a dilution refrigerator and coupled to a classical computing device that is also included in the dilution refrigerator, according to some embodiments.

FIG. 24B is high-level diagram illustrating an example neuro-thermodynamic computer comprising multiple thermodynamic chips (e.g., that implement respective energy-based models (EBMs) and a relay gadget) included in respective dilution refrigerators and coupled to respective classical computing devices that are also included in the respective dilution refrigerators, according to some embodiments.

FIG. 25 is high-level diagram illustrating an example neuro-thermodynamic computer comprising one or more thermodynamic chips (e.g., that implement respective energy-based models (EBMs) and a relay gadget) coupled to a classical computing device in an environment other than a dilution refrigerator, according to some embodiments.

FIG. 26 is a high-level diagram illustrating oscillators included in a substrate of a thermodynamic chip and a mapping of the oscillators to logical neurons or synapses of the thermodynamic chip, according to some embodiments.

FIG. 27 is an additional high-level diagram illustrating oscillators included in a substrate of a thermodynamic chip mapped to logical neurons, weights, and biases (e.g., synapses) of a neuro-thermodynamic computing system, according to some embodiments.

FIG. 28 is a block diagram illustrating an example computer system that may be used in at least some embodiments.

While embodiments are described herein by way of example for several embodiments and illustrative drawings, those skilled in the art will recognize that embodiments are not limited to the embodiments or drawings described. It should be understood, that the drawings and detailed description thereto are not intended to limit embodiments to the particular form disclosed, but on the contrary, the intention is to cover all modifications, equivalents and alternatives falling within the spirit and scope as defined by the appended claims. The headings used herein are for organizational purposes only and are not meant to be used to limit the scope of the description or the claims. As used throughout this application, the word “may” is used in a permissive sense (i.e., meaning having the potential to), rather than the mandatory sense (i.e., meaning must). Similarly, the words “include,” “including,” and “includes” mean including, but not limited to. When used in the claims, the term “or” is used as an inclusive or and not as an exclusive or. For example, the phrase “at least one of x, y, or z” means any one of x, y, and z, as well as any combination thereof.

### DETAILED DESCRIPTION

The present disclosure relates to methods, systems, and an apparatus for performing computer operations using a thermodynamic chip and more specifically to relaying an expectation value of one or more degrees of freedom of oscillators belonging to an energy based model (EBM) to other oscillators, which may be oscillators of a second energy base model (EBM), such as components of a neuro-thermodynamic computing device, while maintaining information in a thermodynamic state. This can be contrasted with other approaches to communicate information that involve reading out thermodynamic information, such as using a classical computing device, and then relaying the information in classical form. For example, the ability to relay thermodynamic information directly between components in a neuro-thermodynamic computer avoids issues associated with readout to a classical computing device, such as read-out error, loss of information, and/or delays associated with performing readout. Moreover, if the information is to be used by another component of a neuro-thermodynamic computing device, relay of the information in a thermodynamic state avoids other delays such as would be incurred if required to initialize a receiving component to have an initial state corresponding to a state of the thermodynamic information that was read out from another component, wherein the relayed information is not already in a thermodynamic state. In some embodiments, such relay techniques as described herein may be used to relay thermodynamic information, such as expectation value of one or more degrees of freedom, between energy-based models (EBMs). Such energy-based models (EBMs) may include trained models that evolve according to Langevin dynamics, and which may be used to generate inferences, such as machine learning (ML) inferences. For example, an ML model used to generate an ML inference may be physically implemented as a trained energy-based model (EBM).

A relay gadget allows controlling thermal information flow without having to rely on varying mass and frequency combinations between components to drive the thermodynamic information flow. For example, a relay gadget includes one or more relay oscillators that respectively have a controllably adjustable mass and/or frequency that can be used to couple oscillators belonging to other modules. A relay gadget may include a controller that controls couplings at least between relay oscillators themselves and between relay oscillators and oscillators belonging to other modules. This allows controlled thermodynamic information flow without having to worry about relative mass and/or frequency sizing between oscillators of the components as described below (e.g. such as oscillators of an input EBM and oscillators of a destination EBM). For example, using a relay oscillator reduces the required constraints on the selection of parameters for oscillators belonging to different modules. The relay oscillator can also be used to obtain samples from various degrees of freedom of an oscillator. Such samples can be used to do Gibbs sampling.

Multiple types of computations, such as mean field forwards and backwards propagation can be greatly accelerated when implemented on a thermodynamic processor, where the individual components of such models are oscillators implemented on superconducting circuit elements. However, in many applications, the desired operations need to be performed on circuits with multiple components (with each component performing a particular computation), which can add significant constraints on the selection of parameters for each of the oscillator of the thermodynamic chip. For example, if frequency or mass differentials (or combinations of both) between oscillators are used to cause thermodynamic information flow to move analog information between components in a desired manner, there are a limited number of easily achievable frequency and mass combinations of oscillators. Thus, the complexity of such systems quickly becomes self-limiting due to the inability to achieve thermodynamic information flow when primarily relying on mass and/or frequency differentials between oscillators to guide information flow. For example, in order to achieve thermodynamic information flow, it may be necessary that a value of mass times frequency squared of a sending oscillator is much greater than a corresponding value of mass times frequency squared of a receiving oscillator. As such, having the ability to modularize large circuits, with each modular component responsible for a particular task is needed for implementing such models using thermodynamic processors. In such a modularized approach, mass and/or frequency differentials can be used within a given model, but a relay gadget can be used to relay information between modules, without a need to consider oscillator parameters of a given module when selecting oscillator parameters of another module. This modularization greatly simplifies the selection of oscillator parameters.

In some embodiments, relay oscillators may be implemented using a fully analog scheme. In such embodiments, secondary oscillators may optionally be included with respective ones of the relay oscillators, wherein secondary oscillators act as a bias (e.g., bias oscillator). Bias oscillators may be used to enable respective ones of the relay oscillators to maintain respective equilibrium values of the respective ones of the relay oscillators for longer time scales as a coupling between a relay oscillator and an output oscillator from one of the modules is turned off. Also, in some embodiments, relay oscillator has a time dependent mass and constant frequency, and in other embodiments the relay oscillator has a constant mass but time-dependent frequency.

In some embodiments, a neuro-thermodynamic processor may be configured such that learning algorithms for learning parameters of an energy-based model may be applied using Langevin dynamics. For example, as described herein, a thermodynamic chip of a neuro-thermodynamic processor may be configured such that, given a Hamiltonian that describes an energy-based model, weights and biases (e.g., synapses) may be calculated based on measurements taken from the thermodynamic chip as it naturally evolves according to Langevin dynamics. For example, a positive phase term, a negative phase term, and associated gradients needed to determine updated weights and biases for the energy-based model may be simply computed on an accompanying classical computing device, such as a field programmable gate array (FPGA) or application specific integrated circuit (ASIC), based on measurements taken from the oscillators of the thermodynamic chip. Such calculations performed on the accompanying classical computing device may be simple and non-complex as compared to other approaches that use the classical computing device to determine statistical probabilities (e.g., without using a thermodynamic chip). Also, in some embodiments, weights and biases used in an energy-based model may be determined iteratively, for example wherein a classical computing device is used to generate updated weights and biases, and wherein resulting inference performance is compared to training data to determine whether additional iterative learning is needed.

In some embodiments, physical elements of a thermodynamic chip may be used to physically model evolution according to Langevin dynamics. For example, in some embodiments, a thermodynamic chip includes a substrate comprising oscillators implemented using superconducting flux elements. The oscillators may be mapped to neurons (visible or hidden) that “evolve” according to Langevin dynamics. For example, the oscillators of the thermodynamic chip may be initialized in a particular configuration and allowed to thermodynamically evolve. As the oscillators “evolve” degrees of freedom of the oscillators may be sampled. Values of these sampled degrees of freedom may represent, for example, vector values for neurons or synapses that evolve according to Langevin dynamics. For example, algorithms that use stochastic gradient optimization and require sampling during training, such as those proposed by Welling and Teh, and/or other algorithms, such as natural gradient descent, mirror descent, etc. may be implemented using a thermodynamic chip. In some embodiments, a thermodynamic chip may enable such algorithms to be implemented directly by sampling the neurons and/or synapses (e.g., degrees of freedom of the oscillators of the substrate of the thermodynamic chip) without having to calculate statistics to determine probabilities. As another example, thermodynamic chips may be used to perform autocomplete tasks, such as those that use Hopfield networks, which may be implemented using the Welling and Teh algorithm. For example, visible neurons may be arranged in a fully connected graph (such as a Hopfield network, etc.), and the values of the auto complete task may be learned using the Welling and Teh algorithm. In some embodiments, a relay gadget may be used to sample visible neurons of a first energy-based model (EBM). Furthermore, the relay gadget may relay an expectation value of one or more degrees of freedom of an output oscillator (e.g. visible neurons) of the first energy-based model (EBM), based on one or more sample values sampled by the relay gadget, to an input of another EBM device.

In some embodiments, a thermodynamic chip includes superconducting flux elements arranged in a substrate, wherein the thermodynamic chip is configured to modify magnetic fields that couple respective ones of the oscillators with other ones of the oscillators. In some embodiments, non-linear (e.g., anharmonic) oscillators are used that have dual-well potentials. These dual-well oscillators may be mapped to neurons of a given energy-based model that the thermodynamic chip is being used to implement. Also, in some embodiments, at least some of the oscillators may be harmonic oscillators with single-well potentials. In some embodiments, oscillators may be implemented using superconducting flux elements with varying amounts of non-linearity. In some embodiments, an oscillator may have a single well potential, a dual-well potential, a potential somewhere in a range between a single-well potential and a dual-well potential, or a multi-well potential. In some embodiments, visible neurons may be mapped to oscillators having a single well potential, a dual-well potential, a potential somewhere in a range between a single-well potential and a dual-well potential, or a multi-well potential. In some embodiments, the potential of an oscillator may be engineered in such a way that the expectation value corresponds to an activation function of a node in a machine learning (ML) model, or some other function of interest.

In some embodiments, oscillators of a thermodynamic chip may also be used to represent values of weights and biases of the energy-based model. Thus, weights and biases that describe relationships between neurons may also be represented as dynamical degrees of freedom, e.g., using oscillators of the thermodynamic chip (e.g., synapse oscillators).

In some embodiments, parameters of an energy-based model or other learning algorithm may be learned through evolution of the oscillators of a thermodynamic chip.

As mentioned above, in some embodiments, the weights and biases of an energy-based model may be dynamical degrees of freedom (e.g., oscillators of a thermodynamic chip), in addition to neurons (hidden or visible) being dynamic degrees of freedom (e.g., represented by other oscillators of the thermodynamic chip). In such configurations, gradients needed for learning algorithms can be obtained by performing sampling of the synapse oscillators, such as position samples or momentum samples. For example, measurements of the synapse oscillators (position or momentum) performed on a time scale proportional to a thermalization time of the synapse oscillators, or on shorter time scales than the thermalization times of the synapse oscillators, can be used to compute time-averaged gradients in addition to space averaged gradients. In some embodiments, the variance of the time averaged or space averaged gradient (determined using synapse oscillator measurements) scales as 1/t where t is the total measurement time. These gradients can be used to calculate new weights and bias values that may be used as synapse values in an updated version of the energy-based model. The process of making measurements and determining updated weights and biases may be repeated multiple times until a learning threshold for the energy-based model has been reached.

For example, there are various learning algorithms where one must use both positive and negative phase terms to perform parameter updates. For instance, in the implementation by Welling and Teh the parameters are updated as follows:

$${θ}_{t + 1} = {θ}_{t} + \frac{{ϵ}_{t}}{2} ( - {∇}_{{θ}_{t}} {ε}_{p} ( {θ}_{t} ) - N \frac{1}{n} {\sum }_{i = 1}^{n} {∇}_{{θ}_{t}} ε ( {θ}_{t} , {x}_{{t}_{i}} ) + {𝔼}_{x ∼ {p}_{{θ}_{t}} ( x )} [ {∇}_{{θ}_{t}} ε ( {θ}_{t} , x ) ] ) + {η}_{t}$$

where εₚ(θₜ) is some prior potential and the probability distribution for an energy-based model (EBM) with parameters θₜ given by pθₜ(x)=e^{-ε(θ}^{ₜ}^{,x)}/Z, where Z is a partition function. The gradient term

$$N \frac{1}{n} {\sum }_{i = 1}^{n} {∇}_{{θ}_{t}} ε ( {θ}_{t} , {x}_{{t}_{i}} )$$

where the visible nodes are clamped to the data will be referred to as the positive phase term. The gradient term

$${𝔼}_{x ∼ {p}_{{θ}_{t}} ( x )} [ {∇}_{{θ}_{t}} ε ( {θ}_{t} , x ) ] ,$$

where the visible nodes are sampled from x˜pθₜ(x) will be referred to as the negative phase term (e.g., where the visible nodes are unclamped). When hidden neurons are present, the parameter update rule is given by:

$${θ}_{t + 1} = {θ}_{t} + \frac{{ϵ}_{t}}{2} ( - {∇}_{{θ}_{t}} {ε}_{p} ( {θ}_{t} ) - N \frac{1}{n} {\sum }_{i = 1}^{n} {𝔼}_{z ∼ {p}_{{θ}_{t}} ( z \vert {x}_{{t}_{i}} )} [ {∇}_{{θ}_{t}} ε ( {θ}_{t} , {x}_{{t}_{i}} , z ) ] + {𝔼}_{( x , z ) ∼ {p}_{{θ}_{t}} ( x , z )} [ {∇}_{{θ}_{t}} ε ( {θ}_{t} , x , z ) ] ) + {η}_{t}$$

For a neuro-thermodynamic processor, which includes visible neurons coupled via weights and biases that are also represented by degrees of freedom (e.g., synapse oscillators), the dynamics of the system for a three-body coupling between the synapse oscillators and the neuron oscillators (visible or hidden) may be described by a Hamiltonian. Examples of Hamiltonians are given later in the specification.

Broadly speaking, classes of algorithms that may benefit from implementation using a thermodynamic chip include those algorithms that involve probabilistic inference. Such probabilistic inferences (which otherwise would be performed using a CPU or GPU) may instead be delegated to the thermodynamic chip for a faster and more energy efficient implementation. At a physical level, the thermodynamic chip harnesses electron fluctuations in superconductors coupled in flux loops to model Langevin dynamics. In some embodiments, architectures such as those described herein may resemble a partial self-learning architecture, wherein classical computing device(s) (e.g., a FPGA, ASIC, etc.) may be relied upon only to perform simple tasks such as summing measured values and performing other non-compute intensive operations in order to implement a learning algorithm.

Note that in some embodiments, electro-magnetic or mechanical (or other suitable) oscillators may be used. A thermodynamic chip may implement neuro-thermodynamic computing and therefore may be said to be neuromorphic. For example, the neurons implemented using the oscillators of the thermodynamic chip may function as neurons of a neural network that has been implemented directly in hardware. Also, the thermodynamic chip is “thermodynamic” because the chip may be operated in the thermodynamic regime slightly above 0 Kelvin, wherein thermodynamic effects cannot be ignored. For example, some thermodynamic chips may be operated within the milli-Kelvin range, and/or at 2, 3, 4, etc. degrees Kelvin. The term thermodynamic chip also indicates that the thermal equilibrium dynamics of the neurons are used to perform computations. In some embodiments, temperatures less than 15 Kelvin may be used. Though other temperatures ranges are also contemplated. This also, in some contexts, may be referred to as analog stochastic computing. In some embodiments, the temperature regime and/or oscillation frequencies used to implement the thermodynamic chip may be engineered to achieve certain statistical results. For example, the temperature, friction (e.g., damping) and/or oscillation frequency as well as masses, may be controlled variables that ensure the oscillators evolve according to a given dynamical model, such as Langevin dynamics. In some embodiments, temperature may be adjusted to control a level of noise introduced into the evolution of the neurons. As yet another example, a thermodynamic chip may be used to model energy models that require a Boltzmann distribution. Also, a thermodynamic chip may be used to solve variational algorithms and perform learning tasks and operations. A thermodynamic chip may also be used to train deep learning architectures using mean field forwards and backwards propagation approaches.

In some embodiments, it is desired to transfer an expectation value of one energy-based model (EBM) to another EBM. In some embodiments an instantaneous sample value may be transferred from an output oscillator of one EBM to an input oscillator of another EBM. Furthermore, respective output oscillators of respective EBM blocks may have a potential well, and the respective output oscillators may be coupled to one or more oscillators in respective EBM blocks The instantaneous sample value of a of an output oscillator of a given EBM will follow a probability distribution associated with the potential well of the output oscillator and couplings of the output oscillator with the one or more oscillators belonging to the first EBM. An instantaneous sample value of the state of the output oscillator may be any possible value within the bounds of the potential well and respective couplings. In some instances, the instantaneous sample value of the output oscillator may be far off from the expectation value (e.g. due to thermodynamic fluctuations, anharmonic potentials, multiple well potentials, the coupling between the output oscillator with other oscillators belonging to a shared EBM, or a combination of factors). Furthermore, the output oscillator of an EBM may hop between wells of a potential, thus the expectation value may not be a probable outcome of an instantaneous sample of the output oscillator.

In some embodiments, forwards and backwards propagation between an output oscillator and an input oscillator via a relay gadget is desired. In the case where an expectation value of an output oscillator is propagated in a forward direction (e.g. from an output oscillator of an EBM to an input oscillator of another EBM), propagation of an expectation value of an input oscillator in a backwards direction (e.g. from the input oscillator of the other EBM to the output oscillator of the EBM) may also be performed.

In some embodiments, approximations of an expectation value of a generic potential well may be thermodynamically transferred by utilizing a relay gadget with at least one or more relay oscillator and an additional relay oscillator as described herein. Sample values that a relay oscillator may represent are at least derivable from instantaneous sample values. In some embodiments, a relay oscillator may take an instantaneous sample value. In some embodiments, a relay oscillator may take a sample value based on a plurality of instantaneous sample values over a period of time. In some embodiments, a relay oscillator may take on a value based on another relay oscillator.

In some embodiments of utilizing a relay gadget, multiple blocks of energy based models (EBMs) may be used, wherein a given block is responsible for performing a portion of a computation which is part of some larger system. In some embodiments, this may comprise training the parameters of EBMs using mean-field forwards and backwards propagation. In such settings, an expectation value of an output of a given EBM is used as input to a next EBM block, where the expected value is the result of a computation performed by a deterministic function (e.g. relay gadget). A relay gadget may relay the expectation value from one EBM to another EBM.

In some embodiments, to enable an expectation value of an output of an EBM to be used as as input to a subsequent EBM in a fully analogue fashion (e.g. without the use of measurements), two or more relay oscillators may be used. In some embodiments, an expectation value is derivable from one or more sample values. In some embodiments, relay oscillators may be oscillators which may be arranged between the output of a given EBM and the input of an additional EBM in such a way that their state may be configured to take on a sample value of the output oscillators of a given EBM. In some embodiments, sample values may be collected in such a way (e.g. spatial or temporal arrangement of relay oscillators as described below) that a close approximation of an expectation value of an output of a given EBM may be represented on one or more relay oscillators. Classical controllers may be used to turn the couplings on and off between the output oscillators and relay oscillators, between respective relay oscillators, as well as to make the masses and frequencies of the relay oscillators time-dependent. Nevertheless, measurements may not be required, and the timing of the operations may be computed during the compilation step.

In some embodiments, a relay gadget may include a group of one or more relay oscillators and an additional relay oscillator. One or more relay oscillators of the group of relay oscillators may be coupled to an output oscillator of a first EBM. The one or more relay oscillators may be coupled in such a way that respective sample values of the output oscillator of the first EBM, wherein the output oscillator has progressed through thermodynamic evolution, may be stored on respective ones of the relay oscillators of the first group of one or more relay oscillators. An additional relay oscillator may be coupled to one or more of the relay oscillators, wherein the coupling enables the additional relay oscillator to take on an expectation value of the output oscillator, wherein the expectation value is derivable based at least in part on the sample values. In some embodiments, bias oscillators may be used. In some embodiments, bias oscillators may not be used. For simplicity, some embodiments are given with bias oscillators and some embodiments are given without bias oscillators, however, that does not limit the embodiment to only one way or the other.

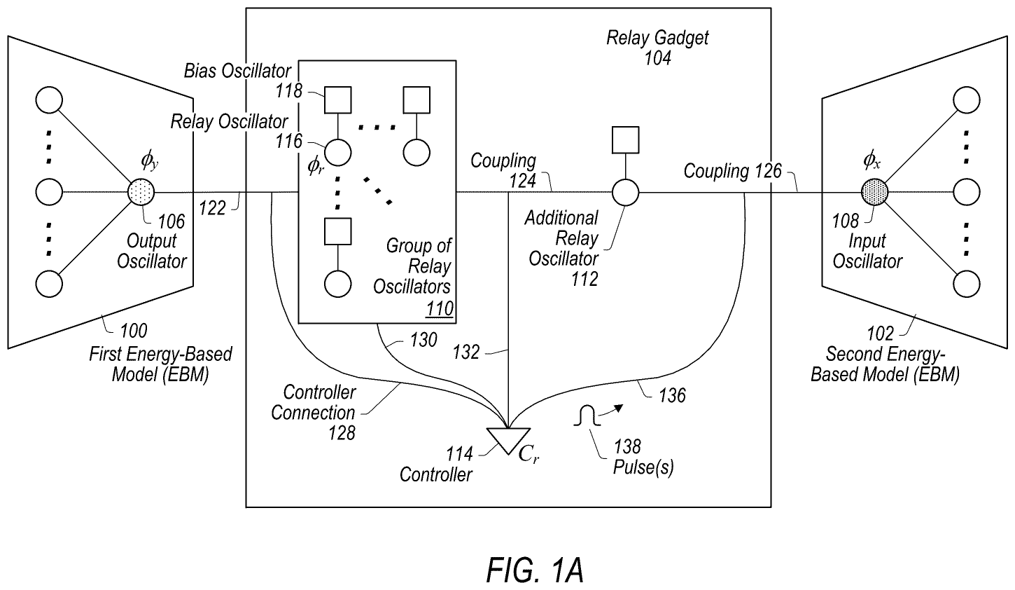

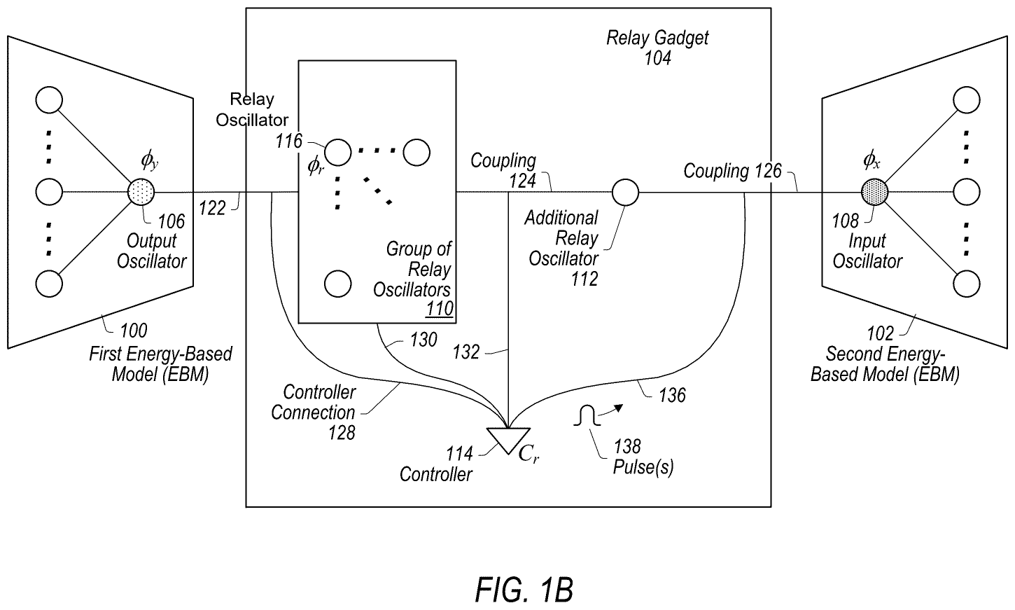

FIG. 1A is a high-level diagram illustrating an output oscillator, an input oscillator, and a relay gadget, wherein the relay gadget comprises a group of relay oscillators and is configured to relay thermodynamic information between the output oscillator and the input oscillator and includes bias oscillators, according to some embodiments.

In some embodiments, thermodynamic information is relayed from a first energy-based model (EBM) 100 to a second energy-based model (EBM) 102 via relay gadget 104. The thermodynamic information of EBM 100 is outputted via output oscillator 106 and inputted into input oscillator 108 via relay gadget 104. The thermodynamic information may include, for example, samples of thermodynamic equilibrium of output oscillator 106, or the expectation value of the output oscillator 106. The expectation value is at least derivable based on samples values of the output oscillator 106. Output oscillator 106 may be governed by a potential wherein the potential follows a single-well potential, double-well potential, multi-well potential, or any generic potential that may be engineered. The output oscillator 106 may also be coupled to other oscillators belonging to EBM 100.

In some embodiments, an expectation value of one or more degrees of freedom of output oscillator 106 may be influenced by a potential of output oscillator 106 as well as couplings between output oscillator 106 and one or more oscillators belonging to first energy-based model 100. Potentials governing the dynamics of the output oscillator 106 may have multiple wells. With generic arbitrary potentials (e.g. multiple wells) and coupling between output oscillator 106 and one or more oscillators belonging to first energy-based model 100, the position degrees of freedom of the output oscillators can hop between wells. As described herein, a relay gadget provides a solution to approximate an expectation value of the output oscillator. Furthermore, utilizing the expectation value allows for forwards and backwards propagation. For example, using an approximated expectation value in forwards and backwards propagation may provide better results than using a sample value, as the expectation value better represents the state of the oscillator whose degree of freedom value is being relayed to a second oscillator.

Relay gadget 104 comprises a group of relay oscillators 110 and an additional relay oscillator 112. The group of relay oscillators 110 comprises one or more relay oscillators arranged with respective bias oscillators (e.g., relay oscillator 116 arranged with bias oscillator 118). As described later, relay oscillators in oscillator group 110 may be configured and coupled in various ways (e.g. temporally and spatially) to transfer thermodynamic information. The additional relay oscillator 112 is connected to bias oscillator 120. As discussed later, the additional relay oscillator 112 may be configured and coupled in various ways to transfer thermodynamic information. For example, the group of relay oscillators 110 transfers thermodynamic information to additional relay oscillator 112 via coupling 124. Coupling 124 may be controlled by on-chip classical controller 114.

Output oscillator 106 is coupled to the one or more relay oscillators of the group of relay oscillators 110 via on-chip classical controller 114. On-chip classical controller 114 may send a pulse or a group of pulses to cause couplings between oscillators (e.g., coupling between output oscillator 106 and relay oscillator 116) or relay oscillators like 116 and a bias oscillator like 118 via 130. Coupling is represented by coupling 122, 124, 126 and oscillators may be coupled or not coupled. When coupling is on, parameters of respective coupled oscillators affect the other oscillator it is coupled to. Couplings between oscillators within the group of relay oscillators 110 are not expressly shown in FIG. 1 to emphasize that the coupling may take different configurations (e.g. temporal or spatial configurations as detailed below). Nevertheless, on-chip classical controller 114 may cause a first set of one or more pulses to be emitted through controller connection 128, wherein the first set of pulses couples one or more relay oscillators of the group of relay oscillators 110 to the output oscillator 106 (e.g., turn on coupling 122). The on-chip classical controller 114 is further configured to cause a second set of one or more pulses to be emitted through 132, wherein the second set of pulses couples one or more relay oscillators of the group of relay oscillators 110 to the additional relay oscillator 112 (e.g., turn on coupling 124). The on-chip classical controller 114 is further configured to cause a third set of one or more pulses (for example, set of pulses 138) to be emitted, wherein the third set of pulses 138 couples the additional relay oscillator 112 to the input oscillator 108 (e.g., turn on coupling 126).

In some embodiments, an additional relay oscillator 112 takes on an expectation value of an output oscillator 106 based at least in part on a coupling or couplings between a group of relay oscillators 110, wherein respective relay oscillators of group 110 comprise respective sample values of the output oscillator 106. The additional relay oscillator 112 may take on the expectation value of output oscillator 106 based at least on respective sample values taken on by respective relay oscillators. Furthermore, additional relay oscillator 112 may transfer the taken on expectation value to input oscillator 108 via controller 114 causing coupling 126 to turn on.

FIG. 1B is a high-level diagram illustrating an output oscillator, an input oscillator, and a relay gadget, wherein the relay gadget comprise a group of relay oscillators and is configured to relay thermodynamic information between the output oscillator and the input oscillator, wherein the relay gadget does not include bias oscillators, according to some embodiments.

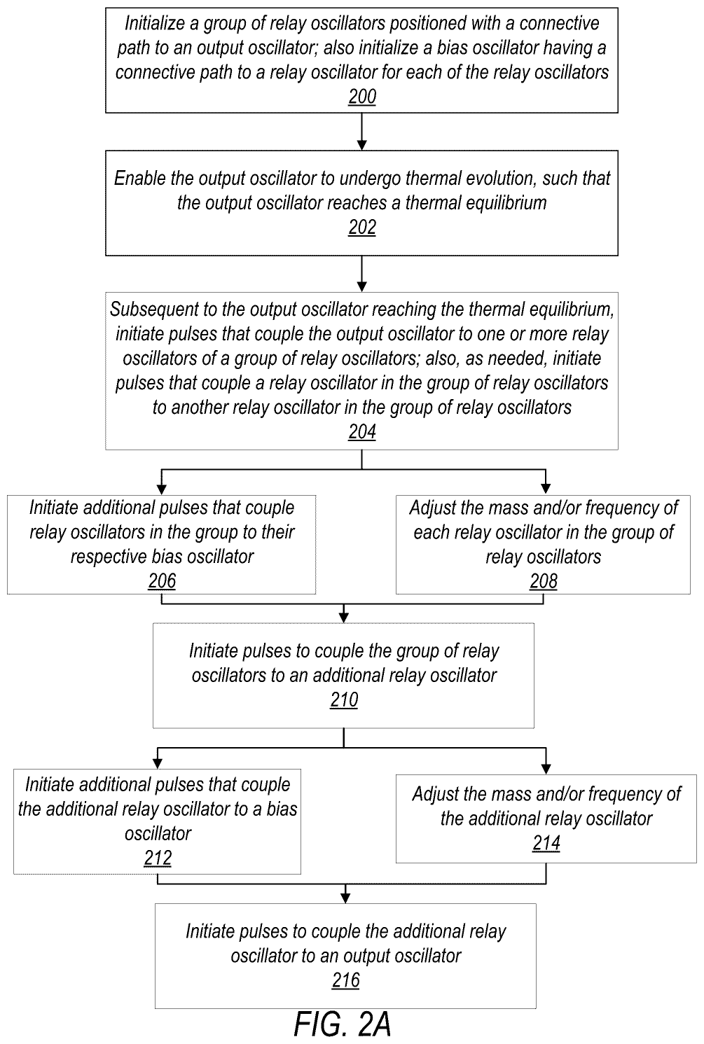

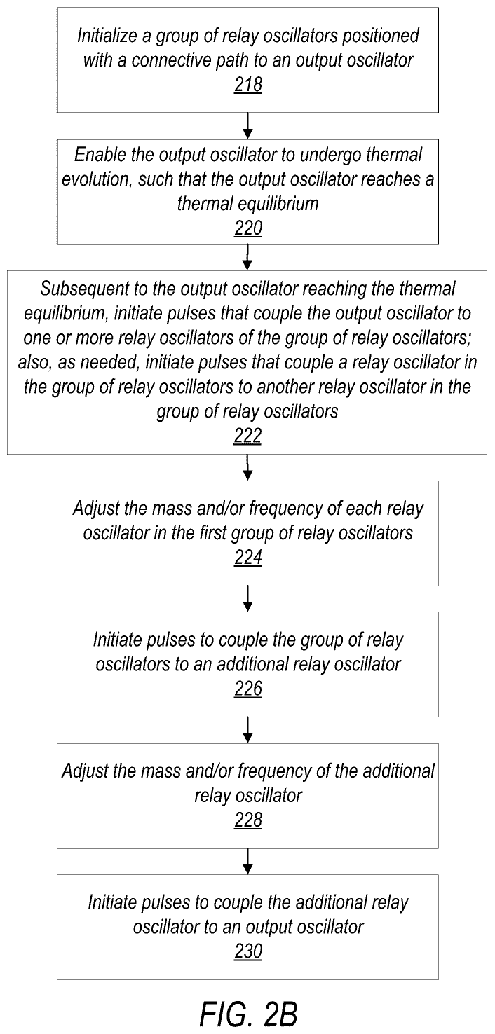

FIG. 2A is a high-level flowchart illustrating a process of relaying thermodynamic information between an output oscillator and an input oscillator, according to some embodiments.

According to some embodiments, the steps consist of initializing a group of relay oscillators positioned with a connective path to an output oscillator; also initializing a bias oscillator having a connective path to a relay oscillator for each of the relay oscillators 200. Enabling the output oscillator to undergo thermal evolution, such that the output oscillator reaches a thermal equilibrium 202. Subsequent to the output oscillator reaching the thermal equilibrium, initiating pulses that couple the output oscillator to one or more relay oscillators of a group of relay oscillators; also, as needed, initiating pulses that couple a relay oscillator in the group of relay oscillators to another relay oscillator in the group of relay oscillators 204. Initiating additional pulses that couple relay oscillators in the group to their respective bias oscillator 206. Adjusting the mass and/or frequency of each relay oscillator in the group of relay oscillators 208. Initiating pulses to couple the group of relay oscillators to the additional relay oscillator 210. Initiating additional pulses that couple the additional relay oscillator to its bias oscillator 212. Adjusting the mass and/or frequency of the additional relay oscillator 214. Initiating pulses to couple the additional relay oscillator to an output oscillator 216.

FIG. 2B is a high-level flowchart illustrating a process of relaying thermodynamic information between an output oscillator and an input oscillator, wherein the process of relaying the thermodynamic information does not require the use of bias oscillators, according to some embodiments.

According to some embodiments, the steps consist of initializing a group of relay oscillators positioned with a connective path to an output oscillator 218. Enabling the output oscillator to undergo thermal evolution, such that the output oscillator reaches a thermal equilibrium 220. Subsequent to the output oscillator reaching the thermal equilibrium, initiating pulses that couple the output oscillator to one or more relay oscillators of a group of relay oscillators; also, as needed, initiate pulses that couple a relay oscillator in the group of relay oscillators to another relay oscillator in the group of relay oscillators 222. Adjusting the mass and/or frequency of each relay oscillator in the group of relay oscillators 224. Initiating pulses to couple the group of relay oscillators to the additional relay oscillator 226. Adjusting the mass and/or frequency of the additional relay oscillator 228. Initiating pulses to couple the additional relay oscillator to an output oscillator 230.

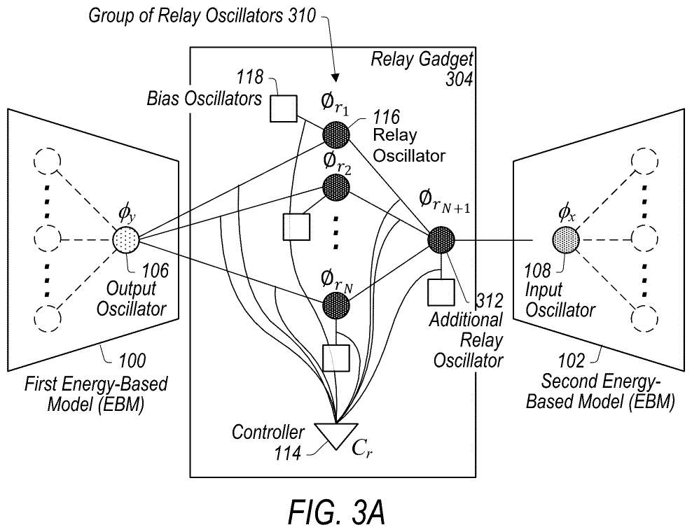

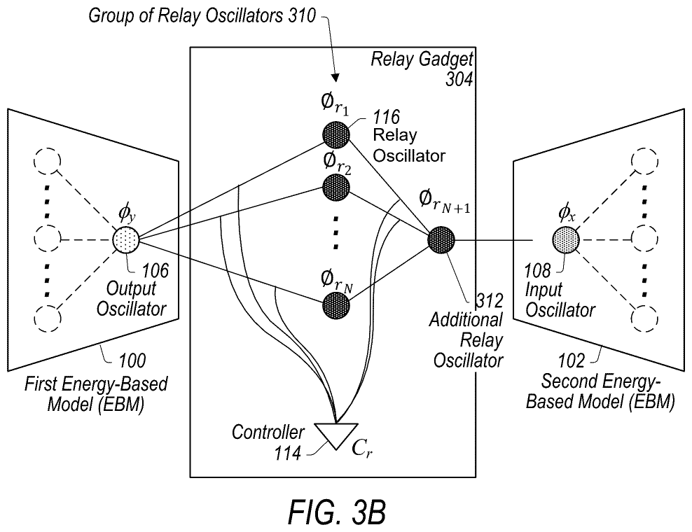

FIG. 3A is a high-level diagram illustrating a spatial analogue relay gadget, wherein respective ones of relay oscillators of a group of relay oscillators are configured to store respective sample values of an output oscillator, according to some embodiments.

In some embodiments, controller 114 sends a first set of one or more pulses wherein the first set of pulses causes output oscillator 106 of first energy-based model (EBM) 100 to be coupled to at least one or more relay oscillators {ϕᵣ_{₁}, ϕᵣ_{₂}, . . . ϕᵣ_{_{N}}}, in the group of relay oscillators 310. The group of relay oscillators 310 comprises a plurality of relay oscillators, wherein respective relay oscillators {ϕᵣ_{₁}, ϕᵣ_{₂}, . . . ϕᵣ_{_{N}}}, are configured to store a sample of the output oscillator 106 based at least in part on respective couplings between the respective ones of the relay oscillators (e.g., 116) of the group of relay oscillators 310 and the output oscillator 106. The on-chip classical controller 114 is further configured to cause another set of one or more pulses to be emitted, wherein the other set of pulses turns off the respective couplings between the output oscillator 106 and the respective ones of the relay oscillator of the group of relay oscillators 310 at different times. This may allow different samples of the output oscillator 106 to be stored on the respective ones of the relay oscillators {ϕᵣ_{₁}, ϕᵣ_{₂}, . . . , ϕᵣ_{_{N}}}.

On-chip classical controller 114 may be further configured to cause a second set of one or more pulses to be emitted, wherein the second set of pulses turns on the coupling between respective ones of the relay oscillators with sample values of the output oscillator 106 to an additional relay oscillator 312. The coupling is configured to transfer an approximation of the expectation value of output oscillator 106 based at least in part on the sample values stored on respective relay oscillators in the first group of relay oscillators 310. Once the additional relay oscillator 312 is tuned to the expectation value of output oscillator 106, controller 114 may cause a set of one or more pulses that may cause the additional relay oscillator to be coupled to input oscillator 108. Later in the disclosure, the relative products of mass and frequency squared of respective oscillators will be discussed.

FIG. 3B is high-level diagram similar to FIG. 3A, wherein the relay gadget does not include bias oscillators, according to some embodiments.

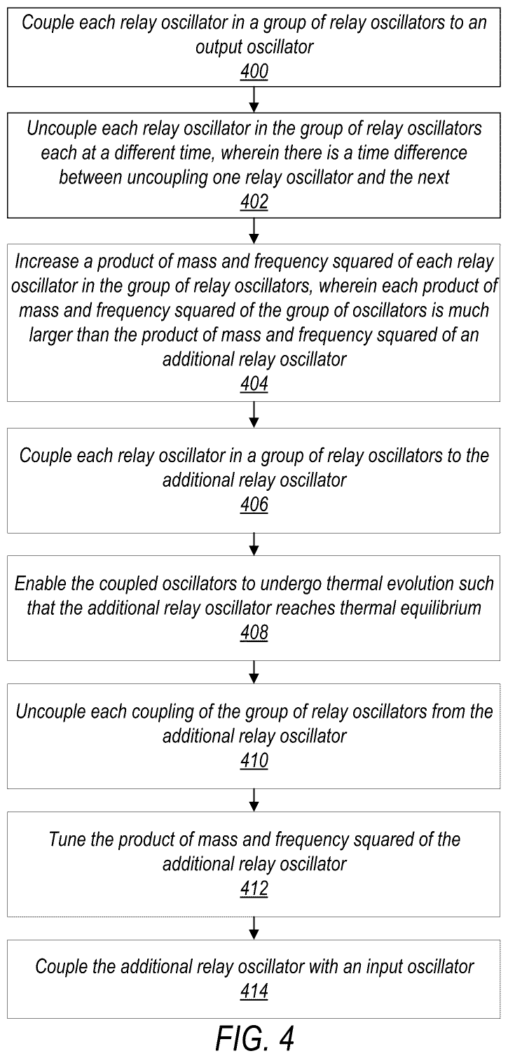

FIG. 4 is a high-level flowchart illustrating a process of extracting an expected value of an output oscillator through samples from a plurality of relay oscillators, wherein respective ones of relay oscillators of a group of relay oscillators are configured to store respective sample values of an output oscillator, according to some embodiments.

In some embodiments, the steps include coupling each relay oscillator in a group of relay oscillators to an output oscillator 400. Uncoupling each relay oscillator in the group of relay oscillators each at a different time, wherein there is a time difference between uncoupling one relay oscillator and the next 402. Increasing a product of mass and frequency squared of each relay oscillator in the group of relay oscillators, wherein each product of mass and frequency squared of the group of oscillators is much larger than the product of mass and frequency squared of an additional relay oscillator 404. Coupling each relay oscillator in the group of relay oscillators to the additional relay oscillator 406. Enabling the coupled oscillators to undergo thermal evolution such that the additional relay oscillator reaches thermal equilibrium 408. Uncoupling each coupling of the group of relay oscillators from the additional relay oscillator 410. Tuning the product of mass and frequency squared of the additional relay oscillator 412. Coupling the additional relay oscillator with an input oscillator 414.

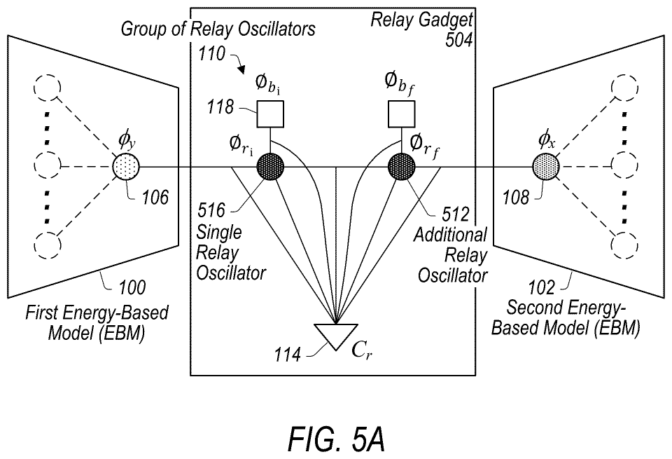

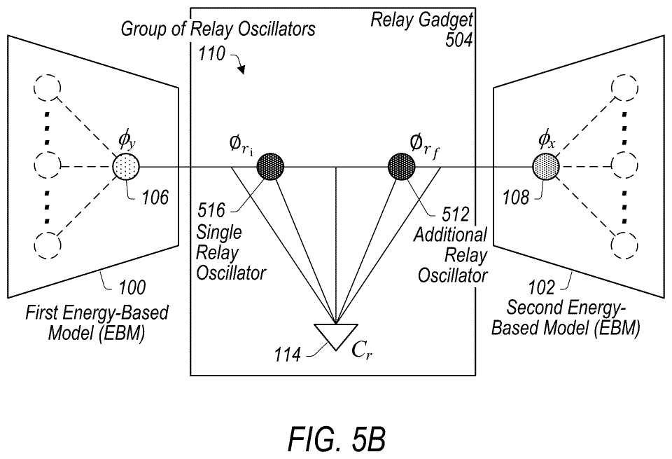

FIG. 5A is a high-level diagram illustrating a temporal analogue relay gadget, wherein a group of relay oscillators comprises a single relay oscillator, according to some embodiments.

In some embodiments, the group of relay oscillators 110 comprises a single relay oscillator 516. The single relay oscillator 516 is configured to store a sample of the output oscillator 106 based at least in part on the coupling between the single relay oscillator 516 and the output oscillator 106. The coupling between output oscillator 106 and single relay oscillator 516 is caused by a first set of one or more pulses emitted from on-chip classical controller 114. The on-chip classical controller 114 is configured to cause a second set of one or more pulses to be emitted, wherein the second set of pulses causes the single relay oscillator 516 to be coupled to additional relay oscillator 512. The sequence of emitting the first set of pulses and then emitting the second set of pulses may be repeated numerous times. Each instance the sequence of the sequential sets of pulses is emitted, the position of additional relay oscillator 512 is incrementally adjusted. Each adjustment may converge the additional relay oscillator 512 to the expectation value of output oscillator 106.

FIG. 5B is high-level diagram similar to FIG. 5A, wherein the relay gadget does not include bias oscillators, according to some embodiments.

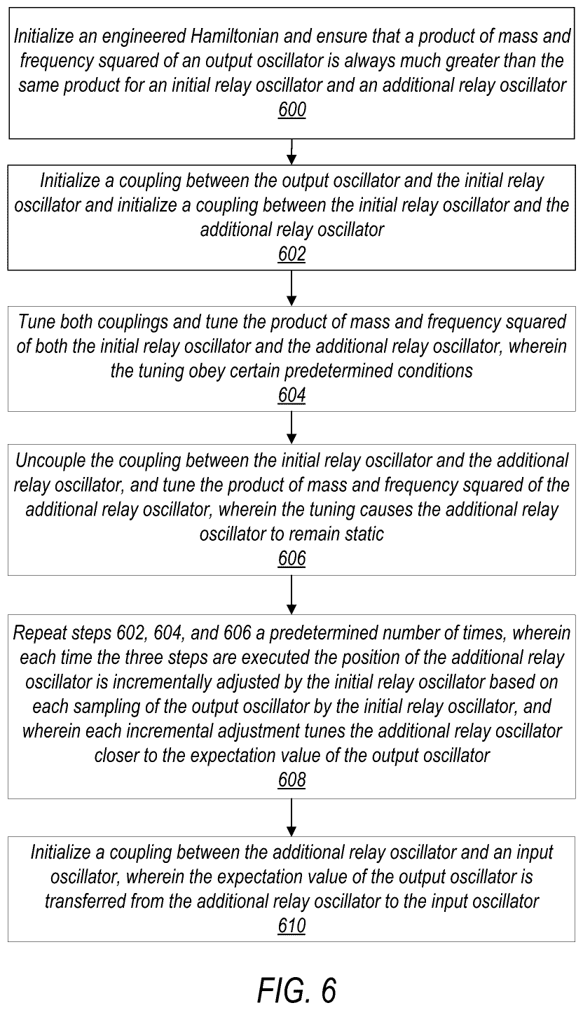

FIG. 6 is a high-level flowchart illustrating a process of extracting an expected value of an output oscillator through sampling the output oscillator at several different times, wherein a group of relay oscillators comprises a single relay oscillator, according to some embodiments.

In some embodiments the steps include initializing an engineered Hamiltonian and ensuring that a product of mass and frequency squared of an output oscillator is always much greater than the same product for an initial relay oscillator and an additional relay oscillator 600. Initializing a coupling between the output oscillator and the initial relay oscillator and initialize a coupling between the initial relay oscillator and the additional relay oscillator 602. Tuning both couplings and tune the product of mass and frequency squared of both the initial relay oscillator and the additional relay oscillator, wherein the tuning obey certain predetermined conditions 604. Uncoupling the coupling between the initial relay oscillator and the additional relay oscillator and tuning the product of mass and frequency squared of the additional relay oscillator, wherein the tuning causes the additional relay oscillator to remain static 606. Repeating the last three steps 602, 604, 606 a predetermined number of times, wherein each time the three steps 602, 604, 606 are executed the position of the additional relay oscillator is incrementally adjusted by the initial relay oscillator based on each sampling of the output oscillator by the initial relay oscillator, and wherein each incremental adjustment tunes the additional relay oscillator closer to the expectation value of the output oscillator 608. Initializing a coupling between the additional relay oscillator and an input oscillator, wherein the expectation value of the output oscillator is transferred from the additional relay oscillator to the input oscillator 610.

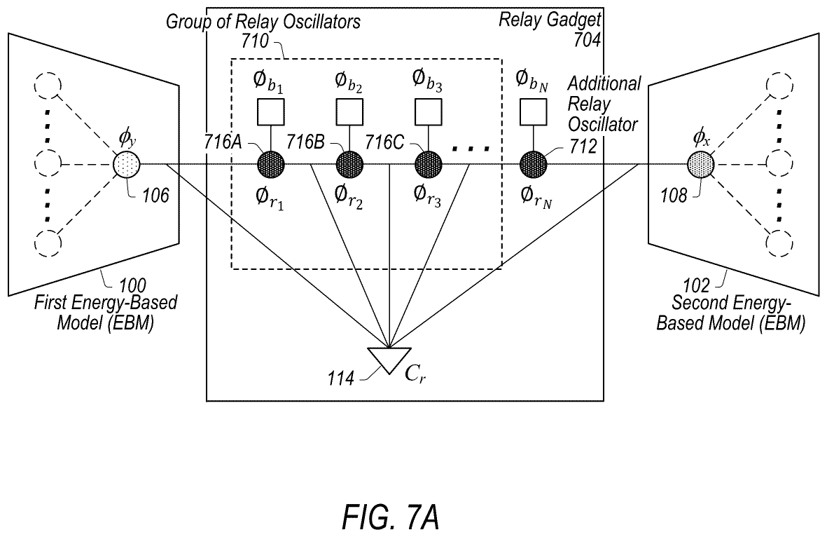

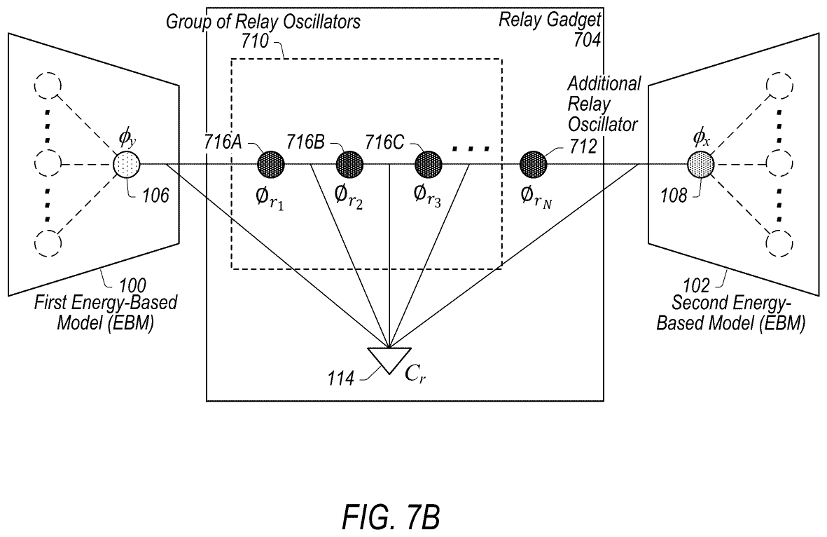

FIG. 7A is a high-level diagram illustrating a series analogue relay gadget, wherein a group of relay oscillators comprises a plurality of relay oscillators arranged in series, according to some embodiments.

FIG. 7A shows a drawing of a series analogue relay gadget 704 such as shown in some embodiments. The group of relay oscillators 110 comprises a plurality of relay oscillators {ϕᵣ_{₁}, ϕᵣ_{₂}, . . . } (e.g. relay oscillator 716A, 716B, 716C) arranged one after another in series. Each relay oscillator has a product of mass and frequency squared. The first relay oscillator 716A, ϕᵣ_{₁}, has the smallest product of mass and frequency squared. The next relay oscillator 716B, ϕᵣ_{₂}, has a product of mass and frequency squared larger than the previous relay oscillator 716A, ϕᵣ_{₁}. This trend of increasing the product of mass and frequency squared continues for each subsequent relay oscillator in the group of relay oscillators 110. As last in the chain of relay oscillators, the additional relay oscillator 712 has the largest product of mass and frequency squared. The couplings between relay oscillators and the coupling between the output oscillator 106 and the first relay oscillator 716A, ϕᵣ_{₁}, may be turned on at the same time and allowed to evolve thermodynamically according to Langevin dynamics. Once coupling is initiated, each successive relay oscillator takes continuous samples of the previous oscillator it is coupled to. Furthermore, each successive relay oscillator may be a closer approximation of the expectation value of the output oscillator 106. In this manner, additional relay oscillator 712 approximates an expectation value of input oscillator 106. At this point, coupling between the additional relay oscillator 712 and input oscillator 108 may be turned on and the thermodynamic information may be transferred to input oscillator 108. The number of relay oscillators and the timing of coupling may be chosen beforehand and optimized for a desired precision or accuracy of the expectation value of the output relay oscillator.

FIG. 7B is high-level diagram similar to FIG. 7A, wherein the relay gadget does not include bias oscillators, according to some embodiments.

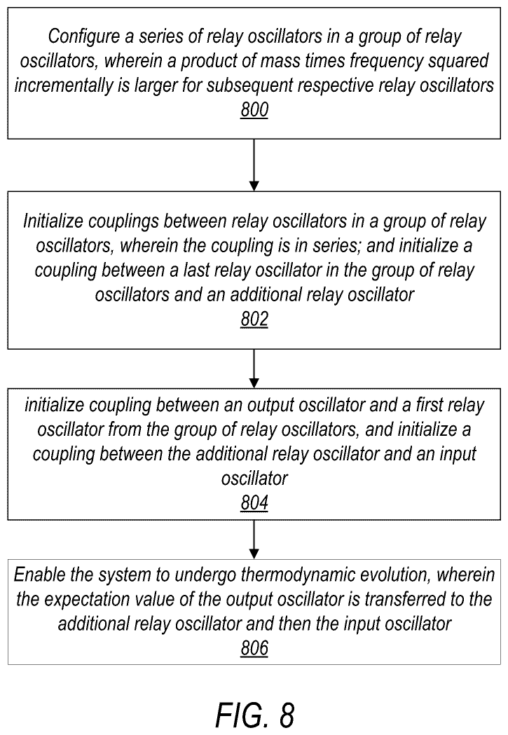

FIG. 8 is a high-level flowchart illustrating a process of extracting an expected value of an output oscillator through sampling the output oscillator, wherein a group of relay oscillators comprises a plurality of relay oscillators arranged in series, according to some embodiments.

According to some embodiments, the steps of utilizing the series analogue relay gadget 704 such as shown in some embodiments is given. The steps include configuring a series of relay oscillators in a group of relay oscillators, wherein a product of mass times frequency squared incrementally is larger for subsequent respective relay oscillators 800. Initializing couplings between relay oscillators in a group of relay oscillators, wherein the coupling is in series; and initializing a coupling between a last relay oscillator in the group of relay oscillators and an additional relay oscillator 802. initializing coupling between an output oscillator and a first relay oscillator from the group of relay oscillators, and initializing a coupling between the additional relay oscillator and an input oscillator 804. Enabling the system to undergo thermodynamic evolution, wherein the expectation value of the output oscillator is transferred to the additional relay oscillator and then the input oscillator 806.

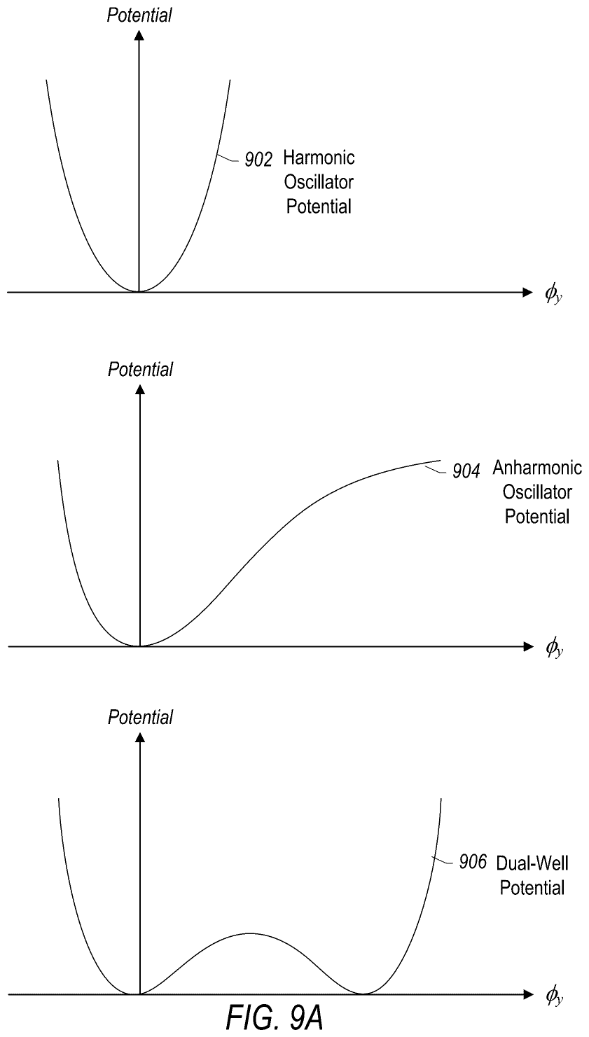

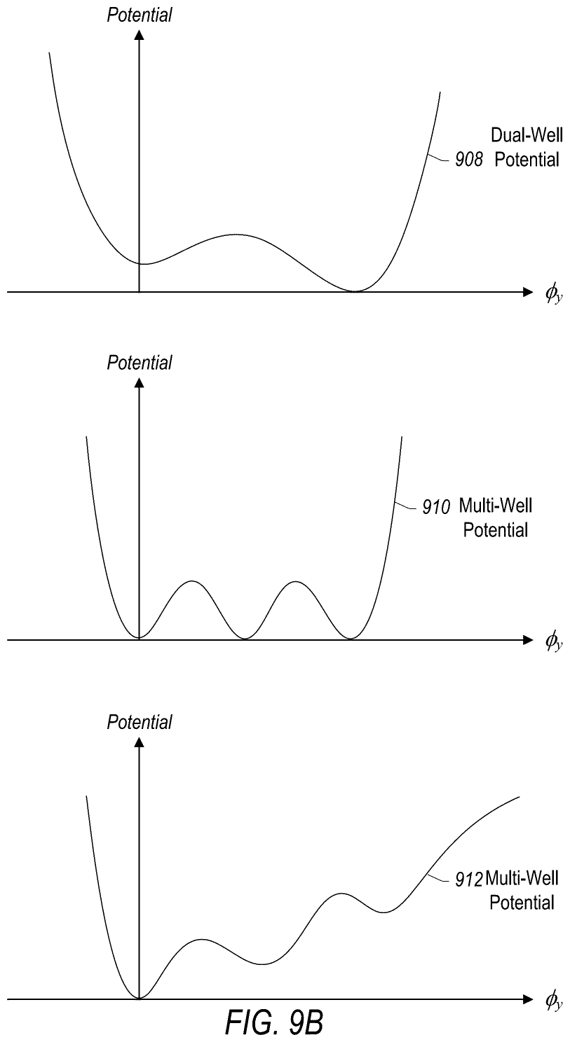

FIG. 9A shows embodiments of possible potentials, according to some embodiments.

Non-limiting examples of potentials that may be engineered to govern output oscillator 106 are given. Harmonic Oscillator Potential 902 illustrates the simple case of a single well potential. Anharmonic oscillator potential 904 illustrates that a single-well potential may be perturbed and not symmetric. Dual-well potential 906 illustrates adding a well to a single well potential.

FIG. 9B shows embodiments of possible potentials, according to some embodiments.

Non-limiting examples of potentials that may be engineered to govern output oscillator 106 are given. Dual-well potential 908 illustrates that the height of each well may be different. Multi-well potential 910 illustrates adding a third well to a dual-well potential. Multi-well potential 912 illustrates three wells each at a different potential height and asymmetry when comparing the ends of the potential. This list of potentials does not exemplify all arbitrary potentials that may be engineered during the design or construction of an EBM. In some embodiments, the expectation value of output oscillator 106 is based at least in part on the potential of output oscillator 106 and one or more couplings between output oscillator 106 and one or more oscillators belonging to the first EBM 100.

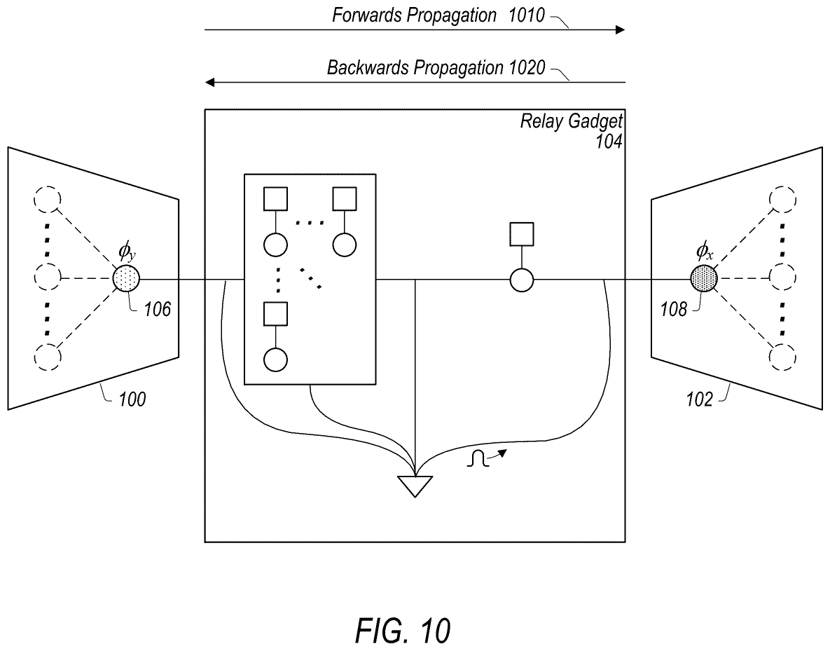

FIG. 10 is a high-level diagram illustrating forward and backward compatibility, wherein a relay gadget may be used to propagate thermodynamic information forwards and backwards and thus respectively emulate and train a deep neural network using energy-based modules, according to some embodiments.

FIG. 10 illustrates that propagation from the output oscillator 106 to the input oscillator 108 is forwards and backwards compatible (e.g. forwards propagation 1010 and backwards propagation 1020). Thermodynamic information can propagate from the output oscillator 106 to the input oscillator 108 via the relay gadget 104 in a forward direction. Furthermore, thermodynamic information can propagate from the input oscillator 108 to the output oscillator 106 via the relay gadget 104 in a backward direction. These propagations may correspond to a compute instance or a training instance of a machine learning (ML) model. In forward propagation, an energy-based model module (e.g. 100 or 102) may be constructed in such a way that thermodynamic evolution enables the expectation value of the output (e.g. 106) of the EBM to correspond to a desired output of a deep learning model. In other words, the EBM can do the same or nearly the same computation as a layer of a desired neural network. Non-limiting examples of output oscillator potentials include potentials described in FIGS. 9A and 9B and may correspond to a SoftMax, sigmoid, or swish activation function. Other functions are also possible, which may be meditated by additional couplings of the output oscillator with other oscillators of an EBM block (not shown), or by using other potentials. Furthermore, forwards and backwards propagation may be propagated via the relay gadget with or without bias oscillators.

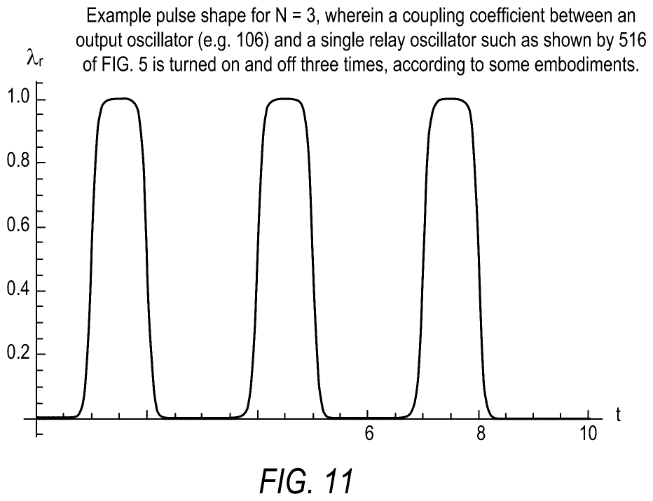

FIG. 11 is an example of a pulse shape, wherein a coupling coefficient between an output oscillator and an initial relay oscillator is turned on and off three times, to impart three different samples of the output oscillator and the initial relay oscillator, according to some embodiments.

FIG. 11 illustrates an example pulse shape for utilizing a temporal analogue relay gadget such as relay gadget 504 of FIG. 5A or FIG. 5B such as shown in some embodiments. In this example, the coupling between input oscillator 106 and the single relay oscillator 516 is turned on and off three times. This may allow three different samples of input oscillator 106 to be used to transfer thermodynamic information such as the expectation value of input oscillator 106 to an additional relay oscillator 512 and ultimately input oscillator 108 as needed. In general, any number of samples may be used to transfer thermodynamic information such as expectation value. The number of samples taken may be predetermined and optimized by experimentation or simulations to find an optimal number of samples the single relay oscillator 516 takes of input oscillator 106.

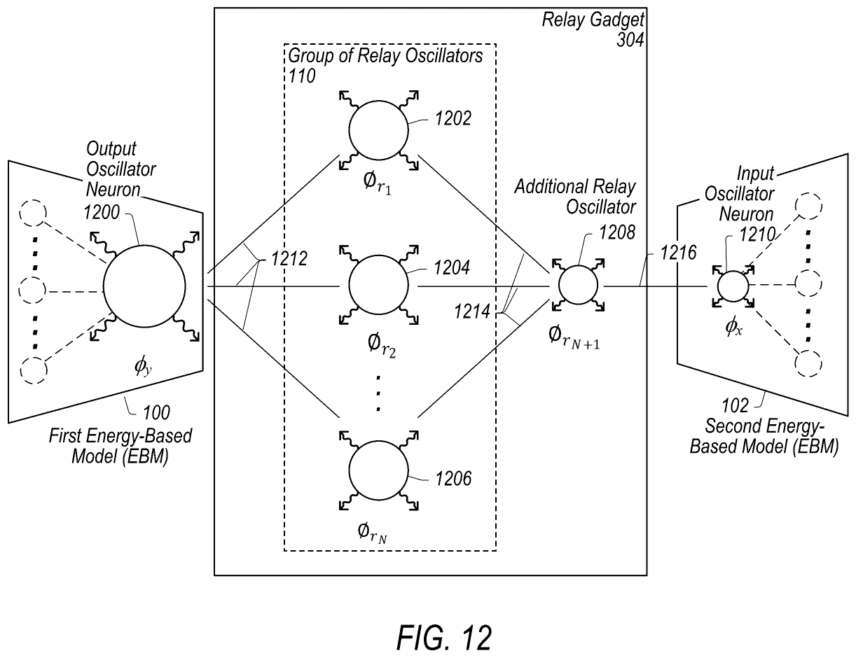

FIG. 12 is a high-level diagram illustrating a spatial analogue relay gadget, wherein respective ones of relay oscillators of a group of relay oscillators are configured to store respective sample values of an output oscillator, wherein the relative size of respective products of mass and frequency squared is represented by a size of respective circles representing an oscillator, according to some embodiments.

In some embodiments, FIG. 12 is a drawing of a spatial analogue relay gadget similar to relay gadget 304 with a representation of the product of mass and frequency squared. In some embodiments only three relay oscillators are in the group of relay oscillators 110. However, there may be more or less depending on the application. In some embodiments, relay gadget 304 may use bias oscillators. Larger sized circles (like input oscillator 1200, relay oscillator 1202, additional relay oscillator 1208 and input oscillator 1210) correspond to a larger product of mass and frequency squared. Each relay oscillator of the group of relay oscillators {ϕᵣ_{₁}, ϕᵣ_{₂}, . . . ϕᵣ_{_{N}}} (e.g. 1202, 1204, 1206) may maintain the same product of mass and frequency squared. Input oscillator 1200 may have a much larger product of mass and frequency squared than each individual relay oscillator {ϕᵣ_{₁}, ϕᵣ_{₂}, . . . ϕᵣ_{_{N}}}. In some embodiments, the product of mass and frequency squared of the relay oscillators may be tuned such that, and the input oscillator 1210 may have a larger product of mass and frequency squared than a product of mass and frequency squared of output oscillator 1200, as long as the relay oscillators have a large enough product of mass and frequency squared after being decoupled from output oscillator 1200 (e.g. 1212) to treat the relay oscillators as static.

In some embodiments, one or more degrees of freedom of output oscillator 1200 may be influenced by a potential of output oscillator 1200 as well as couplings between output oscillator 1200 and one or more oscillators belonging to first energy-based model 100. Potentials governing the dynamics of the output oscillator 1200 may have multiple wells. With generic arbitrary potentials (e.g. multiple wells) and coupling between output oscillator 1200 and one or more oscillators belonging to first energy-based model 100, the position degrees of freedom of the output oscillators can hop between wells. As described herein, a relay gadget provides a solution to approximate an expectation value of the output oscillator. Furthermore, utilizing the expectation value allows for forwards and backwards propagation.

In some embodiments, a relay gadget is presented to be compatible with output oscillator neurons 1200 (belonging to a first EBM module 100) that have multi-well potentials (see FIG. 9). Furthermore, the output oscillator neuron 1200 can be any generic potential. Let the position degree of freedom of the output neuron 1200 be labeled ϕ_{y}. The relay gadget is configured to transfer the expectation value state, [symbol] ϕ_{y}) [symbol] , to some output relay oscillator, ϕᵣ_{_{N+1}} 1208. To do so, an N number of intermediate relay oscillators in a group of relay oscillators {ϕᵣ_{₁}, ϕᵣ_{₂}, . . . ϕᵣ_{_{N}}} 110 may be coupled to the output oscillator neuron, ϕ_{y} 1200 via couplings 1212. The couplings 1212 between the output oscillator ϕ_{y} 1200 and the relay oscillators in the group of relay oscillators {ϕᵣ_{₁}, ϕᵣ_{₂} . . . ϕᵣ_{_{N}}} 110 may be turned off at different times, allowing each of the intermediate relay oscillators to take on different samples at different times. Afterwords, couplings 1214 between the relay oscillators {ϕᵣ_{₁}, ϕᵣ_{₂}, . . . ϕᵣ_{_{N}}} 110 and an additional relay oscillator ϕᵣ_{_{N+1}} 1208 is turned on. For a large enough value of N, the relay oscillator ϕᵣ_{_{N+1}} 1208 may be frozen at the average value of all the relay oscillators {ϕᵣ_{₁}, ϕᵣ_{₂}, . . . ϕᵣ_{_{N}}} 110 which approximates the expectation value the input oscillator [symbol] ϕ_{y} [symbol] 1200.

Furthermore, the Hamiltonian, H, for the coupling between the output oscillator 1200 of the first EBM module 100, the intermediate relay oscillators {ϕᵣ_{₁}, ϕᵣ_{₂}, . . . ϕᵣ_{_{N}}} 110, the input relay oscillator ϕᵣ_{_{N+1}} 1208, and optional bias oscillators coupled to all the relay oscillators may be given by the following:

$$H = \frac{{π}_{y}^{2}}{2 {m}_{y}} + {\sum }_{j = 1}^{N} \frac{{π}_{{r}_{j}}^{2}}{2 {m}_{r} ( t )} + \frac{{π}_{{r}_{N + 1}}^{2}}{2 {\tilde{m}}_{r} ( t )} + {\sum }_{j = 1}^{N} \frac{{π}_{{b}_{j}}^{2}}{2 {m}_{b}} + \frac{{π}_{{r}_{{b}_{N + 1}}}^{2}}{2 {\tilde{m}}_{b}} + {{λ}_{y} ( 1 - {ω}_{y} {ϕ}_{y}^{2} )}^{2} + \frac{1}{2} {m}_{r} ( t ) {{ω}_{r} ( t )}^{2} {\sum }_{j = 1}^{N} {ϕ}_{{r}_{j}}^{2} + \frac{1}{2} {\tilde{m}}_{r} ( t ) {{\tilde{ω}}_{r} ( t )}^{2} {ϕ}_{{r}_{N + 1}}^{2} + \frac{1}{2} {m}_{b} {ω}_{b}^{2} {\sum }_{j = 1}^{N} {ϕ}_{{b}_{j}}^{2} + \frac{1}{2} {\tilde{m}}_{b} {\tilde{ω}}_{b}^{2} {ϕ}_{{b}_{N + 1}}^{2} + {\sum }_{j = 1}^{N} {λ}_{{r}_{j}} ( t ) {( {ϕ}_{{r}_{j}} - {ϕ}_{y} )}^{2} + {λ}_{{r}_{N + 1}} ( t ) {\sum }_{j = 1}^{N} {( {ϕ}_{{r}_{N + 1}} - {ϕ}_{{r}_{j}} )}^{2} + {\sum }_{j = 1}^{N} {λ}_{{b}_{j}} ( t ) {ϕ}_{{b}_{j}} {ϕ}_{{r}_{j}} + {λ}_{{b}_{N + 1}} ( t ) {ϕ}_{{b}_{N + 1}} {ϕ}_{{r}_{N + 1}} ,$$

where the subscripts y, r, b, correspond to the output oscillator 1200, a relay oscillator (e.g. 1202, 1204, or 1206), and a bias oscillator respectively; πm, λ, ω, ϕ represent momentum, mass, coupling or strength coefficient, frequency, and position respectively; and the “˜” above a parameter indicates a different value for that given parameter than the parameter without “˜”. Furthermore, the mass or frequencies of the relay oscillators can be time dependent (e.g., m(t) and ω(t)). The term

$${{λ}_{y} ( 1 - {ω}_{y} {ϕ}_{y}^{2} )}^{2}$$

is used to indicate a double well potential (see FIG. 9) as an embodiment of a generic potential. Other embodiments of potentials include but are not limited to, a multi-well potential, anharmonic oscillator potential well and so on. In some embodiments, bias oscillators may not be used by the relay gadget (e.g. ϕ_{b}_{ⱼ}=0 for j=1, 2, . . . , N). Furthermore, the output oscillator ϕ_{y} may be coupled to one or more respective oscillators belonging to a shared EBM block. However, such couplings are not shown in the Hamiltonian above.

Given the Hamiltonian immediately above, and utilizing the subsequent steps, the expectation value of the output oscillator 1200 [symbol] ϕ_{y} [symbol] may be transferred to the output relay oscillator [symbol] ϕᵣ_{_{N+1}} [symbol] 1208. In some embodiments, the condition regarding the product of mass and frequency squared, namely

$${m}_{r} {ω}_{r}^{2} ≪ {m}_{y} {ω}_{y}^{2} ,$$

may be kept for all the intermediate relay oscillators {ϕᵣ_{₁}, ϕᵣ_{₂}, . . . ϕᵣ_{_{N}}} 110. In other words, respective relay oscillators have a product of mass and frequency squared that is much less than the product of mass and frequency squared of the output oscillator 1200. The coupling parameters {λᵣ_{₁}(t), λᵣ_{₂}(t), . . . , λᵣ_{_{N}}(t)} 1212 may be turned on simultaneously or at different times. The relay gadget is configured to get diverse samples encoded in the position degrees of freedom of the relay oscillators {ϕᵣ_{₁}, ϕᵣ_{₂}, . . . ϕᵣ_{_{N}}} 110 To do so, the coupling parameters 1212 is turned off at different time intervals. According to one embodiment, the j^{th} time-dependent coupling parameter λᵣ_{ⱼ}(t) 1212 (for 1≤j≤N) is:

$${λ}_{{r}_{j}} ( t ) = {λ}_{r} ( σ ( {k}_{r} ( t - {t}_{r} ) ) - σ ( {k}_{r} ( t - {t}_{{r}_{j}} ) ) ) ,$$

where σ(x) is the sigmoid function, wherein other functions, such as tanh and many others may be used in place of the sigmoid function. The parameter kᵣ determines how quickly coupling λᵣ_{ⱼ}(t) 1212 is turned on and off, and λᵣ determines the maximum strength of the coupling parameter 1212. According to some embodiments, the same kᵣ and λᵣ parameters for each time-dependent coupling parameters {λᵣ_{₁}(t), λᵣ_{₂}(t), . . . , λᵣ_{_{N}}(t)} 1212 may be used. The parameter tᵣ determines when λᵣ_{ⱼ}(t) is turned on, and in some embodiments the coupling may be chosen to be turned on at the same time for all values of j. Lastly, the parameter tᵣ_{ⱼ} determines when λᵣ_{ⱼ}(t) is turned off and may depend on the value of j. To get diverse samples, the time difference between samples may be based on the thermal equilibrium time

$${τ}_{therm}^{( y )} ,$$

of the oscillator ϕ_{y}, as shown:

$${t}_{{r}_{j + 1}} - {t}_{{r}_{j}} = {ατ}_{therm}^{( y )} ,$$

where α is some constant, wherein according to some embodiments is chosen based on numerical simulations.

As the coupling parameter λᵣ_{ⱼ}(t) 1212 is turned off, the product

$${m}_{r} ( t ) {ω}_{r}^{2} ( t )$$

of the relay oscillators ϕᵣ_{ⱼ} 110 is tuned to about or nearly immobilize the position degree of freedom of the relay oscillators ϕᵣ_{ⱼ} 110 at respective sampled values received from the output oscillator ϕ_{y} 1200. According to one embodiment, a Cooper-pair box can be used to increase the mass mᵣ(t) to be large enough such that

$${m}_{r} {ω}_{r}^{2} >> {\tilde{m}}_{r} {\tilde{ω}}_{r}^{2}$$

in addition to ensuring that each relay oscillator ϕᵣ_{ⱼ} 110 is nearly frozen at the sampled value when coupling parameter λᵣ_{ⱼ}(t) 1212 is turned off. According to some embodiments, a bias oscillator associated with relay oscillator ϕᵣ_{ⱼ} 110 is used to maintain the sampled value from output oscillator ϕ_{y} 1200 when coupling parameter λᵣ_{ⱼ}(t) 1212 is turned off. Thus, the coupling between relay oscillators ϕᵣ_{ⱼ} 110 and the bias oscillator ϕ_{b}_{ⱼ} may be simultaneously turned on when tuning the product mᵣ(t)ωᵣ²(t). This may prolong the decay time of the relay oscillators 110.

After all of the relay oscillators {ϕᵣ_{₁}, ϕᵣ_{₂}, . . . ϕᵣ_{_{N}}} 110 are decoupled from the output oscillator ϕ_{y} 1200 and the position degrees of freedom of each relay oscillator 110 are nearly immobilized to a sampled value of the output oscillator ϕ_{y} 1200, The coupling (e.g., λᵣ_{_{N+1}}(t) 1214) between the relay oscillators 110 and the input oscillator 1208 is turned on. According to some embodiments, the coupling parameter 1214 between the output relay oscillator and the input oscillator may be chosen to be:

$${λ}_{{r}_{N + 1}} ( t ) = {λ}_{{r}_{N + 1}} ( σ ( {k}_{r} ( t - {t}_{1} ) ) - σ ( {k}_{r} ( t - {t}_{2} ) ) )$$

with t₁>tᵣ_{_{N}}. In some embodiments, since

$${m}_{r} {ω}_{r}^{2} >> {\tilde{m}}_{r} {\tilde{ω}}_{r}^{2} ,$$

the relay oscillators {ϕᵣ_{₁}, ϕᵣ_{₂}, . . . ϕᵣ_{_{N}}} 110 may be treated as static at the sample value obtained from respective couplings to ϕ_{y}. For notational simplicity, the sample value on the N relay oscillators may be noted as ϕᵣ_{ⱼ}=yⱼ for 1≤j≤N.

Now, wherein N is large enough and the yⱼ samples are not too correlated (which may depend on the choice of α), the expectation value of the output relay oscillator 1208 is approximately the expectation value of the output oscillator 1200.

Once the relay oscillator ϕᵣ_{_{N+1}} 1208 reaches thermal equilibrium, the coupling λᵣ_{_{N+1}}(t) 1214 may be turned off and the product \tilde{m}ᵣ(t)\tilde{ω}ᵣ(t)² may be tuned so that relay oscillator ϕᵣ_{_{N+1}} 1208 becomes effectively static at the equilibrium value. Afterwords, the input relay oscillator ϕᵣ_{_{N+1}} 1208 may be coupled to the input neuron ϕₓ 1210 of the second EBM module 102 via coupling 1216.

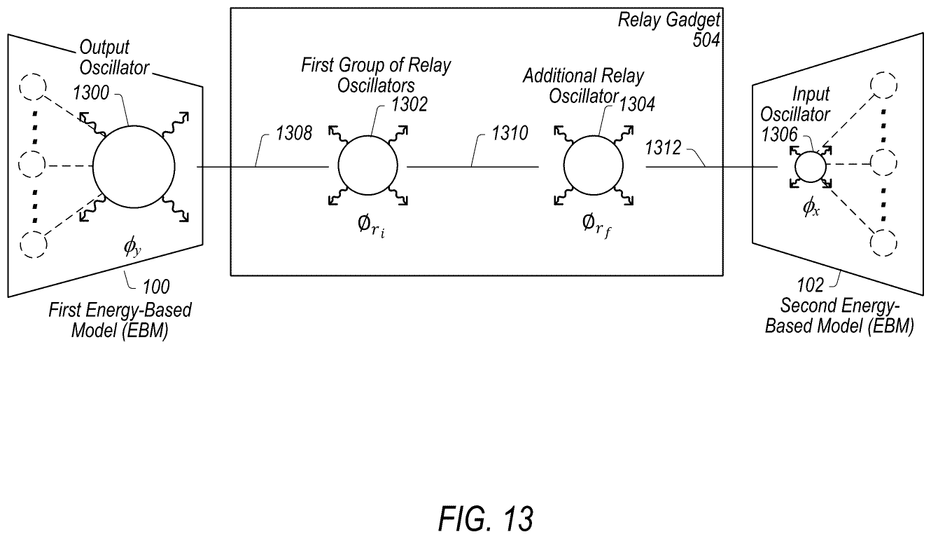

FIG. 13 is a high-level diagram illustrating a temporal analogue relay gadget, wherein a group of relay oscillators comprises a single relay oscillator, wherein the relative size of respective products of mass and frequency squared is represented by a size of respective circles representing an oscillator, according to some embodiments.

Temporal analogue relay gadget similar to relay gadget 504 with a representation of the product of mass and frequency squared is given, according to some embodiments. A temporal analogue relay gadget 504 used to transfer the expectation value of the output oscillator 1300 to the input oscillator 1306 may only require two relay oscillators (e.g., 1302 and 1304). In some embodiments, relay gadget 504 may include bias oscillators. In some embodiment, the initial relay oscillator 1302 with a position degree of freedom, ϕᵣ_{ᵢ}, may be coupled (e.g., coupling 1308) to the output oscillator ϕ_{y} 1300 such that the first relay oscillator 1302 reaches thermal equilibrium to a state of the output oscillator ϕ_{y} 1300 at a given moment in time. Furthermore, an additional relay oscillator 1304, with position degree of freedom ϕᵣ_{_{f}}, may be coupled to the initial relay oscillator ϕᵣ_{ᵢ} 1302. The coupling 1310 between the initial relay oscillator ϕᵣ_{ᵢ} 1302 and the additional relay oscillator ϕᵣ_{_{f}} 1304 may be used to shift the position of the additional relay oscillator ϕᵣ_{_{f}} 1304 based on the current equilibrium value of the initial relay oscillator ϕᵣ_{ᵢ} 1302. The coupling 1308 between the initial relay oscillator ϕᵣ_{ᵢ} 1302 and ϕ_{y} may be repeatedly turned on and off such that ϕᵣ_{ᵢ} 1302 reaches thermal equilibrium to various samples of ϕ_{y} 1300. When the coupling 1308 between ϕᵣ_{ᵢ} and ϕ_{y} may be turned off, the coupling 1310 between ϕᵣ_{ᵢ} 1302 and ϕᵣ_{_{f}} 1304 may be turned on simultaneously such that the position degree of freedom of the additional relay oscillator ϕᵣ_{_{f}} 1304 may be shifted based on the sample state of ϕ_{y} 1300 encoded in ϕᵣ_{ᵢ} 1302. Careful tuning of the masses or frequencies of ϕᵣ_{ᵢ} 1302 and ϕᵣ_{_{f}} 1304 (as well as their coupling coefficients) may need to be performed to ensure that ϕᵣ_{_{f}} 1304 is shifted by the correct amount. Once the coupling 1310 between ϕᵣ_{ᵢ} 1302 and ϕᵣ_{_{f}} 1304 is turned off, the product

$${m}_{{r}_{f}} {ω}_{{r}_{f}}^{2}$$

of the additional relay oscillator 1304 may be tuned to allow ϕᵣ_{_{f}} 1304 to remain nearly static at its new equilibrium value. Furthermore, the product

$${m}_{{r}_{i}} {ω}_{{r}_{i}}^{2}$$

Of the initial relay oscillator 1302 may also be tuned to ensure that the condition

$${m}_{{r}_{i}} {ω}_{{r}_{i}}^{2} << {m}_{y} {ω}_{y}^{2}$$

may be satisfied prior to turning the coupling 1308 back on between ϕᵣ_{ᵢ} 1302 and ϕ_{y} 1300. The number of times the coupling 1308 coefficient between ϕᵣ_{ᵢ} 1302 and ϕ_{y} 1300 is turned on and off is chosen to ensure that enough samples can be used to shift the position of ϕᵣ_{_{f}} 1304 such that its final state is approximately the expectation value of the output oscillator [symbol] ϕ_{y} [symbol] .

In some embodiments, output oscillator 1300 may be influenced by a potential of output oscillator 1300 as well as couplings between output oscillator 1300 and one or more oscillators belonging to first energy-based model 100. Potentials governing the dynamics of the output oscillator 1300 may have multiple wells. With generic arbitrary potentials (e.g. multiple wells) and coupling between output oscillator 1300 and one or more oscillators belonging to first energy-based model 100, the position degrees of freedom of the output oscillators can hop between wells. As described herein, a relay gadget provides a solution to approximate an expectation value of the output oscillator. Furthermore, utilizing the expectation value allows for forwards and backwards propagation.

In some embodiments of a temporal analogue relay gadget, the following Hamiltonian, H, may be used to govern the relay oscillators, output oscillator, and input oscillator as well as coupling between given oscillators and optional bias oscillators:

$$H = \frac{{π}_{y}^{2}}{2 {m}_{y}} + \frac{{π}_{{r}_{i}}^{2}}{2 {m}_{{r}_{i}} ( t )} + \frac{{π}_{{r}_{f}}^{2}}{2 {m}_{{r}_{f}} ( t )} + \frac{{π}_{{r}_{{b}_{i}}}^{2}}{2 {m}_{{b}_{i}}} + \frac{{π}_{{r}_{{b}_{f}}}^{2}}{2 {m}_{{b}_{f}}} + {{λ}_{y} ( 1 - {ω}_{y} {ϕ}_{y}^{2} )}^{2} + \frac{1}{2} {m}_{{r}_{i}} ( t ) {{ω}_{{r}_{i}} ( t )}^{2} {ϕ}_{{r}_{i}}^{2} + \frac{1}{2} {m}_{{r}_{f}} ( t ) {{ω}_{{r}_{f}} ( t )}^{2} {ϕ}_{{r}_{f}}^{2} + \frac{1}{2} {m}_{{b}_{i}} {ω}_{{b}_{i}}^{2} {ϕ}_{{b}_{i}}^{2} + \frac{1}{2} {m}_{{b}_{f}} {ω}_{{b}_{f}}^{2} {ϕ}_{{b}_{f}}^{2} + {λ}_{{r}_{i}} ( t ) {( {ϕ}_{{r}_{i}} - {ϕ}_{y} )}^{2} + {λ}_{{r}_{f}} ( t ) {( {ϕ}_{{r}_{i}} - {ϕ}_{{r}_{f}} )}^{2} + {λ}_{{b}_{i}} ( t ) {( {ϕ}_{{b}_{i}} - {ϕ}_{{r}_{i}} )}^{2} + {λ}_{{b}_{f}} ( t ) {( {ϕ}_{{b}_{f}} - {ϕ}_{{r}_{f}} )}^{2} ,$$

where the terms are similar as previously described. In some embodiments, bias oscillators may not be used by the relay gadget (e.g. ϕ_{b}_{ᵢ}=ϕ_{b}_{_{f}}=0, and λ_{b}_{ᵢ}=λ_{b}_{_{f}}=0). In some embodiments, the coupling coefficients λᵣ_{ᵢ}(t) 1308 and λᵣ_{_{f}}(t) 1310 may be turned on an off multiple times through time. The coupling 1310 between ϕᵣ_{ᵢ} and ϕᵣ_{_{f}} may take on a functional form as follows:

$${λ}_{{r}_{i}} ( t ) = {λ}_{{r}_{i}} {\sum }_{j = 1}^{N} ( σ ( {k}_{{r}_{i}} ( t - {t}_{j}^{( {λ}_{1}^{( i )} )} ) ) - σ ( {k}_{{r}_{i}} ( t - {t}_{j}^{( {λ}_{2}^{( i )} )} ) ) ) ,$$

where the time intervals

$${t}_{j}^{( {λ}_{1}^{( i )} )} and {t}_{j}^{( {λ}_{2}^{( i )} )}$$

for turning the pulse on and off may be found and optimized numerically or experimentally. In some embodiments, the double well potential represented by

$${{λ}_{y} ( 1 - {ω}_{y} {ϕ}_{y}^{2} )}^{2}$$

used in the above Hamiltonian may be replaced by another potential such as a potential shown in FIG. 9A and FIG. 9B. In some embodiments, output oscillator ϕ_{y} (e.g. 1200) may be coupled to one or more oscillators (e.g. illustrated as dashed circles) in a given EBM block (e.g. 100).

When the coupling coefficient λᵣ_{ᵢ}(t) 1308 is turned off, the coupling coefficient λᵣ_{_{f}}(t) 1310 may simultaneously be turned on between ϕᵣ_{ᵢ} 1302 and ϕᵣ_{_{f}} 1304. The masses or frequencies of ϕᵣ_{ᵢ} and ϕᵣ_{_{f}} may also be tuned to ensure that ϕᵣ_{_{f}} 1304 may be shifted by the correct amount. Note that ϕᵣ_{ᵢ} 1302 may be allowed to be perturbed since

$${m}_{{r}_{i}} {ω}_{{r}_{i}}^{2}$$

may be tuned when we coupling 1310 between ϕᵣ_{ᵢ} and ϕᵣ_{_{f}} is turned off to allow the condition

$${m}_{{r}_{i}} {ω}_{{r}_{i}}^{2} << {m}_{y} {ω}_{y}^{2}$$

to be kept prior to turning the coupling 1308 between ϕᵣ_{ᵢ} and ϕ_{y} on again.

In some embodiments, the temporal analogue relay gadget 504 may have the following conditions at some time t′:

$$\vert 4 {λ}_{{r}_{i}} ( {t}^{′} ) {λ}_{{r}_{f}} ( {t}^{′} ) \vert >> \vert {α}_{i} ( {t}^{′} ) {α}_{f} ( {t}^{′} ) \vert$$

$$\vert 4 {λ}_{{r}_{i}} ( {t}^{′} ) {λ}_{{r}_{f}} ( {t}^{′} ) \vert >> \vert 2 {λ}_{{r}_{f}} ( {t}^{′} ) {α}_{i} ( {t}^{′} ) \vert ,$$

wherein the following definitions are used to represent the product of mass and frequency squared: αᵢ(t)≡mᵣ_{ᵢ}(t)ωᵣ_{ᵢ}(t)² and α_{f}(t)≡mᵣ_{_{f}}(t)ωᵣ_{_{f}}(t)².

In some embodiments, the temporal analogue relay gadget may have the following conditions at a time t′:

$$\vert {α}_{i} ( {t}^{′} ) {α}_{f} ( {t}^{′} ) \vert >> \vert 4 {λ}_{{r}_{i}} ( {t}^{′} ) {λ}_{{r}_{f}} ( {t}^{′} ) \vert$$

$$\vert {α}_{i} ( {t}^{′} ) {α}_{f} ( {t}^{′} ) \vert >> \vert 2 {α}_{f} ( {t}^{′} ) ( {λ}_{{7}_{i}} ( {t}^{′} ) + {λ}_{{r}_{f}} ( {t}^{′} ) ) \vert$$

$$\vert {α}_{i} ( {t}^{′} ) {α}_{f} ( {t}^{′} ) \vert >> \vert 2 {λ}_{{r}_{f}} ( {t}^{′} ) {α}_{i} ( {t}^{′} ) \vert$$

wherein the following definitions are used to represent the product of mass and frequency squared: αᵢ(t)≡mᵣ_{ᵢ}(t)ωᵣ_{ᵢ}(t)² and α_{f}(t)≡mᵣ_{_{f}}(t)ωᵣ_{_{f}}(t)². Furthermore, the following additional condition may be used,

$${α}_{i} ( {t}^{′} ) {α}_{f} ( {t}^{′} ) = 4 {λ}_{{r}_{i}} ( {t}^{′} ) {λ}_{{r}_{f}} ( {t}^{′} ) N ,$$

wherein many samples are utilized.

In some embodiments, the parameters αᵢ(t), α_{f}(t) as well as the coupling coefficients λᵣ_{ᵢ}(t) 1308 and λᵣ_{_{f}}(t) 1310 may be periodically tuned in order to achieve the correct dynamics. For example, tuning may be periodically implemented to obey the following conditions:

$$\vert {α}_{i} ( {t}^{′} ) {α}_{f} ( {t}^{′} ) \vert >> \vert 4 {λ}_{{r}_{i}} ( {t}^{′} ) {λ}_{{r}_{f}} ( {t}^{′} ) \vert$$

$$\vert {α}_{i} ( {t}^{′} ) {α}_{f} ( {t}^{′} ) \vert >> \vert 2 {α}_{f} ( {t}^{′} ) ( {λ}_{{r}_{i}} ( {t}^{′} ) + {λ}_{{r}_{f}} ( {t}^{′} ) ) \vert$$

$$\vert {α}_{i} ( {t}^{′} ) {α}_{f} ( {t}^{′} ) \vert >> \vert 2 {λ}_{{r}_{f}} ( {t}^{′} ) {α}_{i} ( {t}^{′} ) \vert$$

$${α}_{i} ( {t}^{′} ) {α}_{f} ( {t}^{′} ) = 4 {λ}_{{r}_{i}} ( {t}^{′} ) {λ}_{{r}_{f}} ( {t}^{′} ) N .$$

In some embodiments, bias oscillators may be included to enable ϕᵣ_{_{f}} 1304 to maintain it's equilibrium value for longer periods of time after the coupling λᵣ_{_{f}}(t) 1310 is turned off. In some embodiments, the parameters αᵢ(t) and α_{f}(t) may be time-independent (e.g., both the masses and frequencies remain constant) wherein

$${m}_{y} {ω}_{y}^{2} >> {α}_{i} ( t ) and {m}_{y} {ω}_{y}^{2} >> {α}_{f} ( t )$$

and the immediately above four conditions remain satisfied. In doing so, only the coupling coefficients λᵣ_{ᵢ}(t) 1308 and λᵣ_{_{f}}(t) 1310 need to be time dependent.

In some embodiments, the coupling 1312 between the additional relay oscillator 104 and the input oscillator 1306 may be turned on, wherein the position of the additional relay oscillator is approximately the expectation value of output oscillator 1300. In some embodiments, input oscillator 1306 may have a product of mass and frequency squared that is the same, smaller than, or larger than a product of mass and frequency squared of output oscillator 1300 insofar as additional relay oscillator 1304 remains static compared to input oscillator 1306. For example, the parameter α_{f}(t) may be tuned to ensure that

$${m}_{x} {ω}_{x}^{2} << {α}_{f} ( t )$$

while coupling 1312 is turned on.

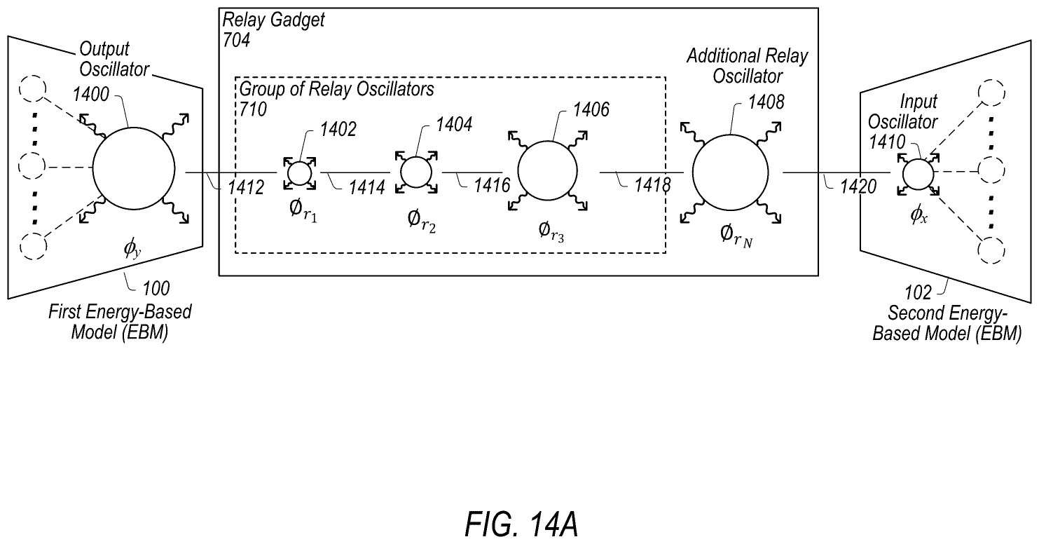

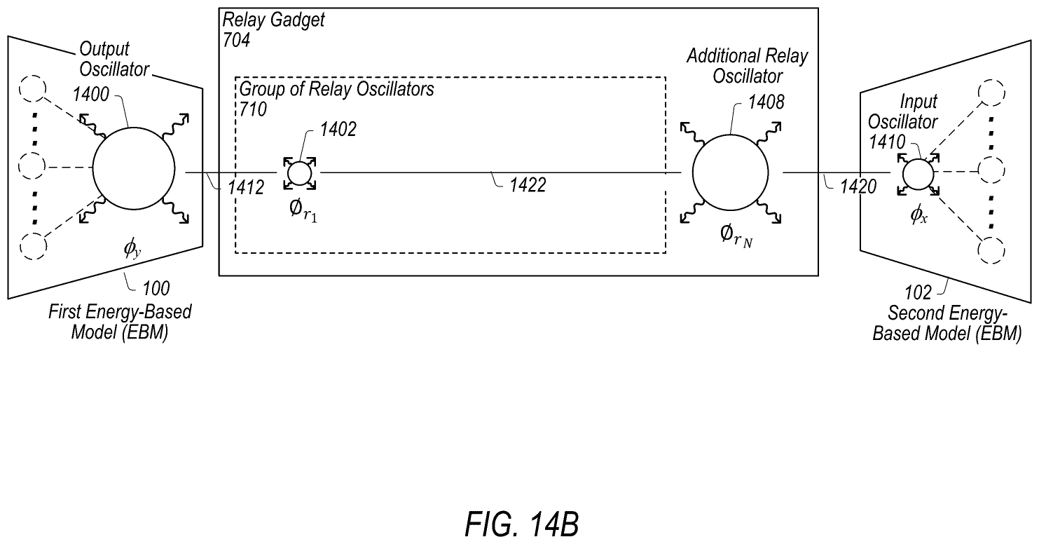

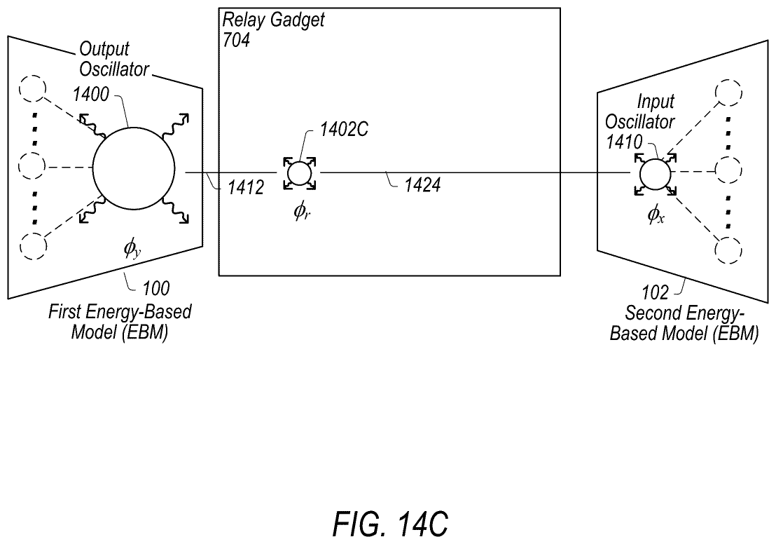

FIG. 14A is a high-level diagram illustrating a series analogue relay gadget, wherein a group of relay oscillators comprises a plurality of relay oscillators arranged in series, wherein the relative size of respective products of mass and frequency squared is represented by a size of respective circles representing an oscillator, according to some embodiments.

A series analogue relay gadget like relay gadget 704 with a representation of the product of mass and frequency squared is shown, according to some embodiments. In some embodiments, relay gadget may include bias oscillators. The series analogue relay gadget 704 is utilized to transfer thermodynamic information between an output oscillator 1400 and an input oscillator 1410. In such an embodiment, a series of coupled relay oscillators (e.g., 1402, 1404, 1406, and 1408) progressively increases the oscillators mass. Having progressively more massive oscillators in series may help reduce the damping requirements for the variance of a single trajectory of the additional relay oscillator to reliably approximate the expectation value of the relay oscillator at a given moment in time. The output oscillator 1400 is coupled 1412 to an initial relay oscillator in a group of relay oscillators 110. Relay oscillator 1402 is coupled (e.g. coupling 1414) to oscillator 1404. Relay oscillator 1404 is coupled (e.g., coupling 1416) to the last relay oscillator 1406 of the group of relay oscillators. The last relay oscillator 1406 is coupled (e.g., coupling 1418) to an additional relay oscillator 1408. While this embodiment only illustrates three relay oscillators in the group of relay oscillators, more relay oscillators or fewer relay oscillators may be used. The number of relay oscillators to use may be found and optimized experimentally or through simulations.

In some embodiments, couplings 1412, 1414, 1416 and 1418 may be turned on at the same or nearly the same time. When the couplings 1412, 1414, 1416 and 1418 are turned on, the system may progress through thermodynamic evolution. The additional relay oscillator 1408 may reach an equilibrium value approximately at the expectation value of the output oscillator 1400. After additional relay oscillator 1408 reaches thermal equilibrium near the expectation value of output oscillator 1400, coupling 1420 may be turned on to allow the expectation value to be relayed to input oscillator 1410.

In some embodiments, output oscillator 1400 may be influenced by a potential of output oscillator 1400 as well as couplings between output oscillator 1400 and one or more oscillators belonging to first energy-based model 100. Potentials governing the dynamics of the output oscillator 1400 may have multiple wells. With generic arbitrary potentials (e.g. multiple wells) and coupling between output oscillator 1400 and one or more oscillators belonging to first energy-based model 100, the position degrees of freedom of the output oscillators can hop between wells. As described herein, a relay gadget provides a solution to approximate an expectation value of the output oscillator. Furthermore, utilizing the expectation value allows for forwards and backwards propagation.

In some embodiments, the potential for a series analogue relay gadget (e.g. 704) may be represented by the following equation:

$${V}_{seq} = \frac{1}{2} {m}_{y} {{ω}_{y}^{2} ( {ϕ}_{y} - c )}^{2} + \frac{1}{2} {\sum }_{j = 1}^{N} {m}_{r}^{( j )} {{ω}_{r}^{( j )} ( t )}^{2} {( {ϕ}_{r}^{( j )} )}^{2} + {λ}_{1} ( t ) {( {ϕ}_{r}^{( 1 )} - {ϕ}_{y} )}^{2} + {\sum }_{j = 2}^{N - 1} {λ}_{j} ( t ) {( {ϕ}_{r}^{( j )} - {ϕ}_{r}^{( j + 1 )} )}^{2} .$$

In the above equation, V_{seq} is a potential of a series analogue relay gadget, N is the number of relay oscillators, m corresponds to mass, ω corresponds to frequency, c corresponds to a previous equilibrium value if any, ϕ corresponds to a positional degree of freedom, λ corresponds to a coupling, and t corresponds to time. Subscripts y, r, 1, and j correspond to an output oscillator, relay oscillator, a first coupling, and a j^{th} coupling respectively. Superscripts in parenthesis indicate an index for a given parameter wherein respective indices indicate respective representations of a given parameter. Note that the potential V_{seq} is related to a Hamiltonian of the series analogue relay gadget, but for simplicity the Hamiltonian is not shown.

In some embodiments, the relay oscillator frequencies may be treated as time independent (e.g. ωᵣ(t) may be written as ωᵣ) insofar as the N^{th} relay oscillator ϕᵣ_{_{N}} (e.g. 1410) has a product of mass and frequency squared such that the N^{th} relay oscillator ϕᵣ_{_{N}} remains static after it is decoupled from the previous N−1 relay oscillator (e.g. 1406).

FIG. 14B is a high-level diagram illustrating a series analogue relay gadget, wherein a group of relay oscillators comprises a single relay oscillator arranged in series with an additional relay oscillator, wherein the relative size of respective products of mass and frequency squared is represented by a size of respective circles representing an oscillator, wherein the size of respective circles can change, according to some embodiments.

In some embodiments, there are two relay oscillators in a series analogue relay gadget: one relay oscillator of a group of relay oscillators (e.g. relay oscillator ϕᵣ_{₁} 1402 from group 710 wherein relay oscillators 1404 and 1406 are not present) and an additional relay oscillator (e.g. additional relay oscillator ϕᵣ_{_{N}} 1408) which may be coupled via coupling 1422. The expectation value of additional relay oscillator ϕᵣ_{_{N}} 1408 may be represented by the following equation,

$$〈 {ϕ}_{{r}_{N}} 〉 = \frac{\int d {ϕ}_{{r}_{N}} {ϕ}_{{r}_{N}} {e}^{- β {V}_{seq}}}{\int d {ϕ}_{{r}_{N}} {e}^{- β {V}_{seq}}}$$

$$= \frac{4 {λ}_{1} {λ}_{N} y}{2 {λ}_{N} ( 2 {λ}_{1} + {α}_{1} ) + {α}_{N} ( 2 ( {λ}_{1} + {λ}_{N} ) + {α}_{1} )} ,$$

wherein λ₁ corresponds to a coupling between an output oscillator ϕ_{y} (e.g. 1400) and a relay oscillator ϕᵣ_{₁} (e.g. 1402), λ_{N} corresponds to a coupling between a relay oscillator (e.g. 1402) and an additional relay oscillator (e.g. 1408) via coupling 1422. The symbol y represents the expectation value of an output oscillator (e.g. 1400). Furthermore, for a given j^{th} component (e.g. j=1, N), αⱼ may be defined as

$${α}_{j} = {{m}_{r}^{( j )} ( {ω}_{r}^{( j )} )}^{2} .$$

Some or all of the couplings λ₁ and λ_{N} (e.g. respectively 1412 and 1422) and parameters α₁ and α_{N} may be time dependent. Given the equation above, in order to relay the expectation value of the output oscillator, y, to the additional relay oscillator (e.g. 1408) the following set of conditions may be met,

$$4 {λ}_{1} {λ}_{N} >> 2 {λ}_{N} {α}_{1} ,$$

$$4 {λ}_{1} {λ}_{N} >> 2 ( {λ}_{1} + {λ}_{N} ) {α}_{{N}^{r}} ,$$

$$and$$

$$4 {λ}_{1} {λ}_{N} >> {α}_{1} {α}_{N} .$$

To satisfy these above conditions, the strength or magnitude of coupling coefficients λ₁ and λ_{N} (e.g. respectively 1412 and 1422) may be tuned. Therefore, in some embodiments, respective products of mass and frequency squared of both relay oscillators (e.g. a product of parameters α₁ and α_{N}) may be much smaller compared to a product of couplings λ₁ and λ_{N}. For example, some change in parameters α₁ and α_{N} will have negligible effect on the expectation value of the additional relay oscillator [symbol] ϕᵣ_{_{N}} [symbol] . Wherein the above conditions are met, the expectation value of the additional relay oscillator may approximate the expectation value of the output oscillator (e.g. [symbol] ϕᵣ_{_{N}} [symbol] ≈y).

In some embodiments, wherein there are two relay oscillators in a series analogue relay gadget, the expectation value of a position of an additional oscillator squared may be described by the following equation,

$$〈 {ϕ}_{{r}_{N}}^{2} 〉 = \frac{\int d {ϕ}_{{r}_{N}} {ϕ}_{{r}_{N}}^{2} {e}^{- β {V}_{seq}}}{\int d {ϕ}_{{r}_{N}} {e}^{- β {V}_{seq}}}$$

$$= \frac{2 {λ}_{N} ( 4 {λ}_{1} ( {λ}_{1} + {λ}_{N} + 2 β {λ}_{1} {λ}_{N} {y}^{2} ) + 2 {α}_{1} ( 2 {λ}_{1} + {λ}_{N} ) + {α}_{1}^{2} ) + {{α}_{N} ( 2 ( {λ}_{1} + {λ}_{N} ) + {α}_{1} )}^{2}}{{β ( 2 {λ}_{N} ( 2 {λ}_{1} + {α}_{1} ) + {α}_{N} ( 2 ( {λ}_{1} + {λ}_{2} ) + {α}_{1} ) )}^{2}} .$$

Insofar as the set of three conditions above are satisfied the equation becomes,

$$\approx \frac{2 {λ}_{N} ( 4 {λ}_{1} ( {λ}_{1} + {λ}_{N} + 2 β {λ}_{1} {λ}_{N} {y}^{2} ) + 2 {α}_{1} ( 2 {λ}_{1} + {λ}_{N} ) + {α}_{1}^{2} ) + {{α}_{N} ( 2 ( {λ}_{1} + {λ}_{N} ) + {α}_{1} )}^{2}}{16 {β ( {λ}_{1} {λ}_{N} )}^{2}} .$$

Rearranging the equation gives,

$$\approx {y}^{2} + \frac{8 {λ}_{1} {λ}_{N} ( {λ}_{1} + {λ}_{N} ) + 4 {α}_{1} {λ}_{N} ( 2 {λ}_{1} + {λ}_{N} ) + 2 {λ}_{N} {α}_{1}^{2}}{16 {β ( {λ}_{1} {λ}_{N} )}^{2}}$$

$$+ \frac{4 {{α}_{N} ( {λ}_{1} + {λ}_{N} )}^{2} + 4 {α}_{1} {α}_{N} ( {λ}_{1} + {λ}_{N} ) + {α}_{N} {α}_{1}^{2}}{16 {β ( {λ}_{1} {λ}_{N} )}^{2}} .$$

In some embodiments, the above equation may simplify to

$$〈 {ϕ}_{{r}_{N}}^{2} 〉 \approx y ,$$

wherein the couplings and a parameters are chosen to obey the following group of conditions,

$$16 {β ( {λ}_{1} {λ}_{N} )}^{2} >> 8 {λ}_{1} {λ}_{N} ( {λ}_{1} + {λ}_{N} )$$

$$16 {β ( {λ}_{1} {λ}_{N} )}^{2} >> 4 {α}_{1} {λ}_{N} ( 2 {λ}_{1} + {λ}_{N} )$$

$$16 {β ( {λ}_{1} {λ}_{N} )}^{2} >> 2 {λ}_{N} {α}_{1}^{2}$$

$$16 {β ( {λ}_{1} {λ}_{N} )}^{2} >> 4 {{α}_{N} ( {λ}_{1} + {λ}_{N} )}^{2}$$

$$16 {β ( {λ}_{1} {λ}_{N} )}^{2} >> 4 {α}_{1} {α}_{N} ( {λ}_{1} + {λ}_{N} )$$

$$16 {β ( {λ}_{1} {λ}_{N} )}^{2} >> {α}_{N} {α}_{1}^{2} .$$

The above group of conditions may be satisfied by selecting special values of the strength of coupling coefficients λ₁ and λ_{N} (e.g. respectively 1412 and 1422) and/or magnitude of α parameters that satisfy the group of conditions. With both the set of conditions and the group of conditions satisfied, the variance of a position of the additional relay oscillator is approximately zero

$$( e . g . Var ( {ϕ}_{{r}_{N}} ) = - 〈 {ϕ}_{{r}_{N}} {〉}^{2} \approx {y}^{2} - {y}^{2} = 0 ) .$$

In some embodiments, parameter α₁ may be chosen to be much less than parameter α_{N}, (e.g. the additional relay oscillator ϕᵣ_{_{N}} 1408 has a much larger product of mass and frequency squared than a product of mass and frequency squared of relay oscillator ϕᵣ_{₁} 1402. In some embodiments, the product of mass and frequency squared of the additional relay oscillator ϕᵣ_{_{N}} 1408 may be time dependent (e.g. α_{N}(t)), by increasing the mass or tuning the frequency after turning off coupling 1422. In some embodiments, a bias oscillator may be coupled to an additional relay oscillator 1408 to maintain the equilibrium value of the additional relay oscillator 1408. A bias oscillator in the potential equation above may include a term such as

$$\frac{1}{2} {m}_{b} {ω}_{b}^{2} {ϕ}_{b}^{2} + {{λ}_{3} ( {ϕ}_{{r}_{2}} - {ϕ}_{b} )}^{2} .$$

FIG. 14C is a high-level diagram illustrating a series analogue relay gadget, wherein a single relay oscillator is used for forwards and backwards propagation.

In some embodiments, a third relay oscillator gadget is presented, where a time-dependent mass is not required. In the case of LRC circuits presented later on, only a time-dependent inductance L is required, while the capacitance can be chosen to be large and constant (wherein the mass is proportional to capacitance).

In some embodiments, the following Hamiltonian for a single-well potential of an output oscillator ϕ_{y} (where the Hamiltonian is no longer treated as a constant). The double-well case is discussed further down. The potential energy function of the system may be represented as

$${V}_{m} = \frac{1}{2} {m}_{y} {{ω}_{y}^{2} ( {ϕ}_{y} - c )}^{2} + \frac{1}{2} {m}_{r} {{ω}_{r} ( t )}^{2} {ϕ}_{r}^{2} + λ ( t ) {( {ϕ}_{r} - {ϕ}_{y} )}^{2} ,$$

where it may be assumed that for the single-well potential, ϕ_{y} has an equilibrium value at approximately c. In some embodiments, the frequency, ωᵣ(t), of relay oscillator 1402C is time-dependent, while the mass, mᵣ, of relay oscillator 1402C is constant. Additionally, bias oscillators are not included in potential Vₘ but bias oscillators may be used in some embodiments (e.g. during the time where ϕᵣ is coupled to ϕ_{y}).

Now given the potential Vₘ by the equation above, the expectation value of relay oscillator 1402C may be written as

$$〈 {ϕ}_{γ} 〉 = \frac{\int d {ϕ}_{r} {ϕ}_{r} {e}^{- β {V}_{m}}}{\int d {ϕ}_{r} {e}^{- β {V}_{m}}}$$

$$= \frac{2 λ {m}_{y} {ω}_{y}^{2}}{( 2 λ + {m}_{y} {ω}_{y}^{2} ) ( {m}_{r} {ω}_{r}^{2} + \frac{2 λ {m}_{y} {ω}_{y}^{2}}{2 λ + {m}_{y} {ω}_{y}^{2}} )} c .$$

In some embodiments, the condition

$${m}_{γ} {ω}_{γ}^{2} << {m}_{y} {ω}_{y}^{2}$$

may be chosen. In the case where

$${m}_{y} {ω}_{y}^{2} << 2λ ,$$

the expectation value of relay oscillator 1402C reduces to

$$〈 {ϕ}_{γ} 〉 \approx \frac{2 λ {m}_{y} {ω}_{y}^{2}}{2 λ ( {m}_{r} {ω}_{r}^{2} + \frac{2 λ {m}_{y} {ω}_{y}^{2}}{2 λ} )} c$$

$$= \frac{{m}_{y} {ω}_{y}^{2}}{{m}_{r} {ω}_{r}^{2} + {m}_{y} {ω}_{y}^{2}} c$$

$$\approx c ,$$

which is the desired result.

In some embodiments, if the conditions

$${m}_{r} {ω}_{r}^{2} << 2λ , {m}_{r} {ω}_{r}^{2} << {m}_{y} {ω}_{y}^{2} and {m}_{y} {ω}_{y}^{2} >> 2λ$$

are chosen, the expectation value of relay oscillator 1402C simplifies to

$$〈 {ϕ}_{γ} 〉 \approx \frac{2 λ {m}_{y} {ω}_{y}^{2}}{{m}_{y} {ω}_{y}^{2} ( {m}_{r} {ω}_{r}^{2} + \frac{2 λ {m}_{y} {ω}_{y}^{2}}{{m}_{y} {ω}_{y}^{2}} )} c$$

$$= \frac{2 λ}{{m}_{r} {ω}_{r}^{2} + 2 λ} c$$

$$\approx c ,$$

which is also the desired result.

In some embodiments, the requirement

$${m}_{r} {ω}_{r}^{2} << {m}_{y} {ω}_{y}^{2}$$

may be satisfied for large value of mᵣ by choosing a small enough value of ωᵣ (which appears as a quadratic term compared to the linear term for mᵣ). At least one advantage of having a large value for mᵣ is that when ϕᵣ is decoupled from ϕ_{y}, ϕᵣ may maintain its equilibrium value without decaying on much larger time scales compared to the case where mᵣ is small. In some embodiments, coupling ϕᵣ to a bias oscillator ϕ_{b} may further extend the decay time after being decoupled from ϕ_{y}.

In some embodiments, when decoupling ϕᵣ and ϕ_{y}, and then turning on the coupling between ϕᵣ and ϕₓ (where ϕₓ is the position degree of freedom of an input oscillator 1410 of a next EBM block 102), it is desired that or be treated as static relative to the dynamics of ϕₓ.

As such, it is required (following the same arguments as above) that

$${m}_{r} {ω}_{r}^{2} << {m}_{y} {ω}_{y}^{2} .$$

Therefore, the frequency ωᵣ may need to be increased after ϕᵣ is decoupled from ϕ_{y}.

In some embodiments using LRC circuits such as described below, the product of mass and frequency squared is written as

$${m}_{r} {ω}_{r}^{2} = \frac{{ϕ}_{0}^{2}}{{L}_{r}} ,$$

where Lᵣ is the inductance used in the circuit for the relay oscillator ϕᵣ. As such, to ensure
that

$${m}_{r} {ω}_{r}^{2} << {m}_{y} {ω}_{y}^{2} ,$$

inductances may be chosen such that Lᵣ>>L_{y}. After decoupling ϕᵣ from ϕ_{y}, Lᵣ may be decreased to ensure that

$${m}_{r} {ω}_{r}^{2} >> {m}_{x} {ω}_{x}^{2} .$$

In some embodiments, a double-well potential is used. The potential using a double-well potential may be written as

$${V}_{m} = {{λ}_{y} ( 1 - {{ω}_{y} ( {ϕ}_{y} - c )}^{2} )}^{2} + \frac{1}{2} {m}_{r} {{ω}_{r} ( t )}^{2} {ϕ}_{r}^{2} + λ ( t ) {( {ϕ}_{r} - {ϕ}_{y} )}^{2}$$

Numerical integration to evaluate the expectation value of relay oscillator 1402C demonstrates that approximate expectation values may be obtained. For example, if the following parameter values are used, λ_{y}=2, ω_{y}=0.5, c=1, β=1, mᵣ=100, ωᵣ=0.0001 and λ=1, the expectation value of the relay oscillator [symbol] ϕᵣ [symbol] ≈0.99998 which is approximately an average value of the double-well potential (since c=1). To further explain, the two global minima are at

$${ϕ}_{y} = c \pm \frac{1}{\sqrt{{ω}_{y}}} .$$

Thus, for small enough ωᵣ, the expectation value is obtained for the double-well potential.

In some embodiments, the oscillators may be implemented in the LRC circuit formalism which is used to encode the oscillator of the EBM model using superconducting circuit elements. In order to translate the aforementioned oscillators to an LRC circuit, the Langevin equation of motion for a system with position q and momentum p governed by a Hamiltonian H is given by:

$$\frac{dq}{dt} = \frac{\partial H}{\partial p}$$

$$\frac{dp}{dt} = - γ p - \frac{\partial H}{\partial p} {\vert}_{t} + \sqrt{\frac{2 m γ}{β}} \frac{{dW}_{t}}{dt} ,$$

where γ is the friction coefficient,

$$β = \frac{1}{{k}_{B} T}$$

(with k_{B} the Boltzmann constant) and Wₜ is a Wienner process.

For LRC circuits, the mass, frequency and friction parameters are given by

$$m = {ϕ}_{0}^{2} C$$

$$ω = \frac{1}{\sqrt{LC}}$$

$$γ = \frac{1}{RC} ,$$

where C is the capacitance, R is the resistance and L the inductance. ϕ₀=Φ₀/(2π) is the reduced flux quantum. The constant Φ₀=h/(2e) is the flux quantum, where h is Planck's constant and e is the fundamental charge. Mass can be made time-dependent if the capacitance is time-dependent. The Langevin equation of motion for an LRC circuit with a time-dependent capacitance can be written as

$$\frac{dC ( t )}{dt} \frac{dq}{dt} + C ( t ) \frac{{d}^{2} q}{{dt}^{2}} = - \frac{1}{R} \frac{dq}{dt} - \frac{1}{{ϕ}_{0}^{2}} \frac{\partial H}{\partial q} {\vert}_{t} + \sqrt{\frac{2}{{ϕ}_{0}^{2} β R}} \frac{{dW}_{t}}{dt} .$$

The product

$$m {ω}^{2} = \frac{{ϕ}_{0}^{2}}{L}$$

which arises from potential terms in the Hamiltonian only depends on the inductance L and not the capacitance C.

In some embodiments, a double-well potential is obtained using the physics of an rf SQUID. The physics of the rf SQUID may be governed by the following parameters: L, an inductance of a main loop, resulting in an inductive energy

$${E}_{L} = {ϕ}_{0}^{2} / 2 L ;$$

I_{c}, a critical current of a junction/DC SQUID, resulting in a Josephson energy E_{J}=ϕ₀I_{c}; C, a capacitance in parallel to the junction/DC SQUID, resulting in a charging energy E_{C}=e²/2C; R a resistance of a resistive channel across a junction, where normal current flows; [symbol] , an external flux coupled into the main loop; and, [symbol] , an external flux coupled into the DC SQUID loop

The motion of the RF SQUID is similar to the motion of a phase “particle” with mass

$$M = {ϕ}_{0}^{2} C$$

and damping

$$η = {ϕ}_{0}^{2} / R$$

evolving in a potential U(φ):

$$U ( φ ) = \frac{{E}_{L}}{2} {( φ - \tilde{{φ}_{L}} )}^{2} + {E}_{J 0} cos ( \frac{\tilde{{φ}_{DC}}}{2} ) ( 1 - cos ( φ ) ) .$$

The potential U(φ) consists of a harmonic well, provided by the inductor, superimposed with a washboard, provided by the Josephson junction. Using the two external fluxes \tilde{φ} and [symbol] it is possible to tune the potential in order to raise a barrier within the harmonic well, as well as tilt the overall shape left and right.

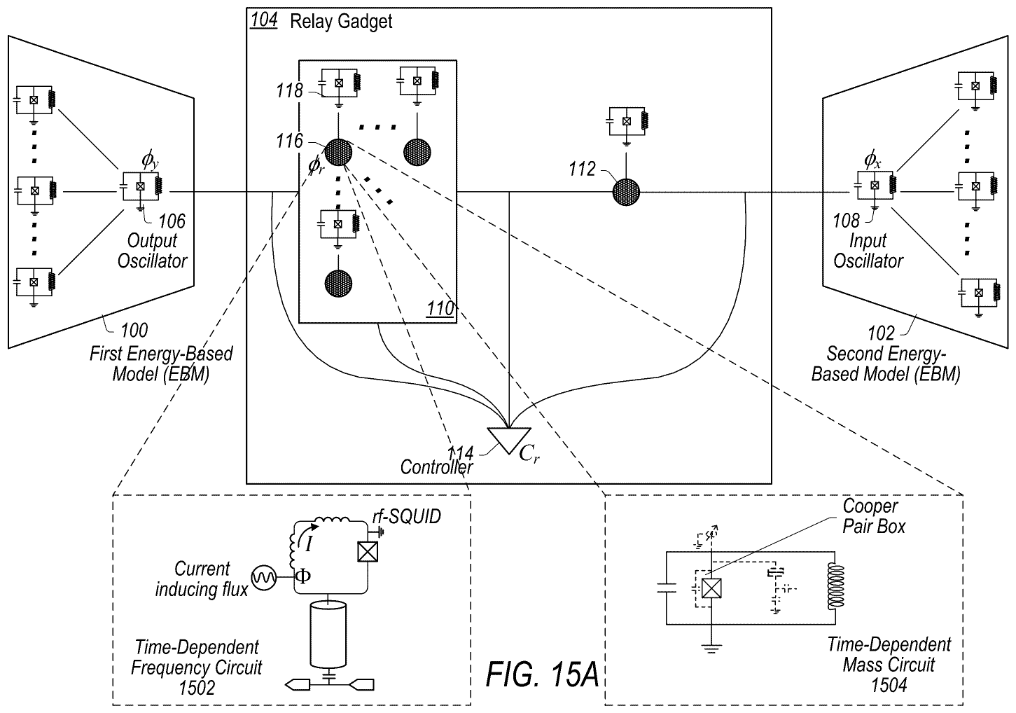

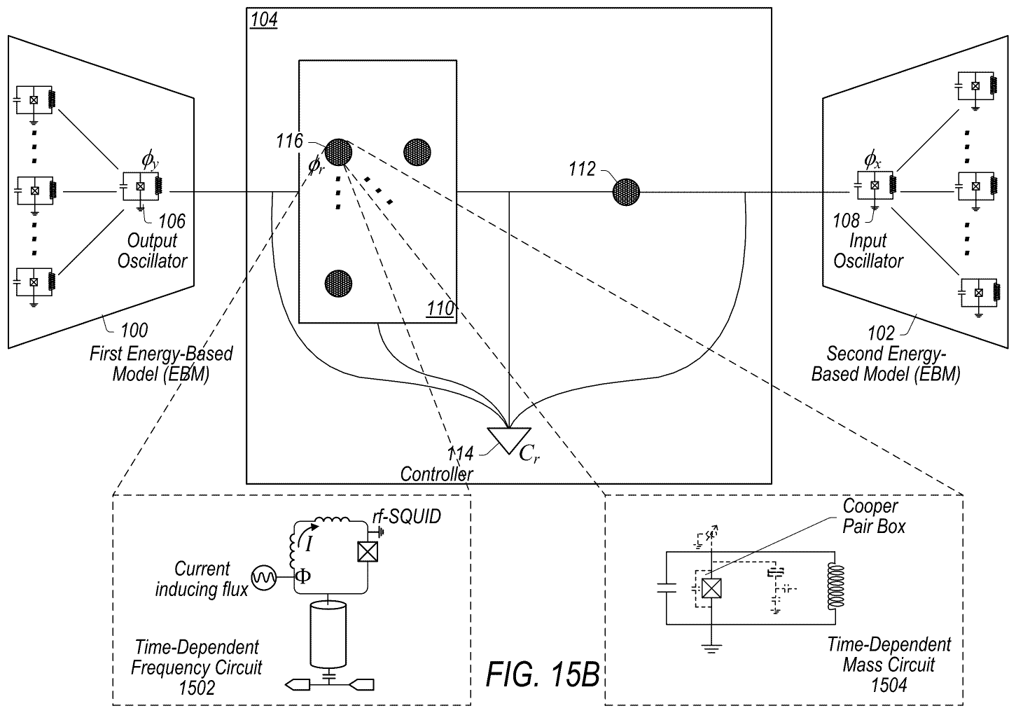

FIG. 15A is a diagram illustrating hardware components that may be used to implement oscillators of a first and second energy-based models (EBMs), as well as two different example hardware configurations of a relay oscillator that have a time-dependent mass or a time-dependent frequency, respectively, according to some embodiments.

Hardware components that may be used to implement oscillators of the first and second energy-based models (EBMs), as well as two different example hardware configurations of a relay oscillator that have a time-dependent mass or a time-dependent frequency, respectively are given, according to some embodiments. In some embodiments, relay gadget 104 may not include bias oscillators.

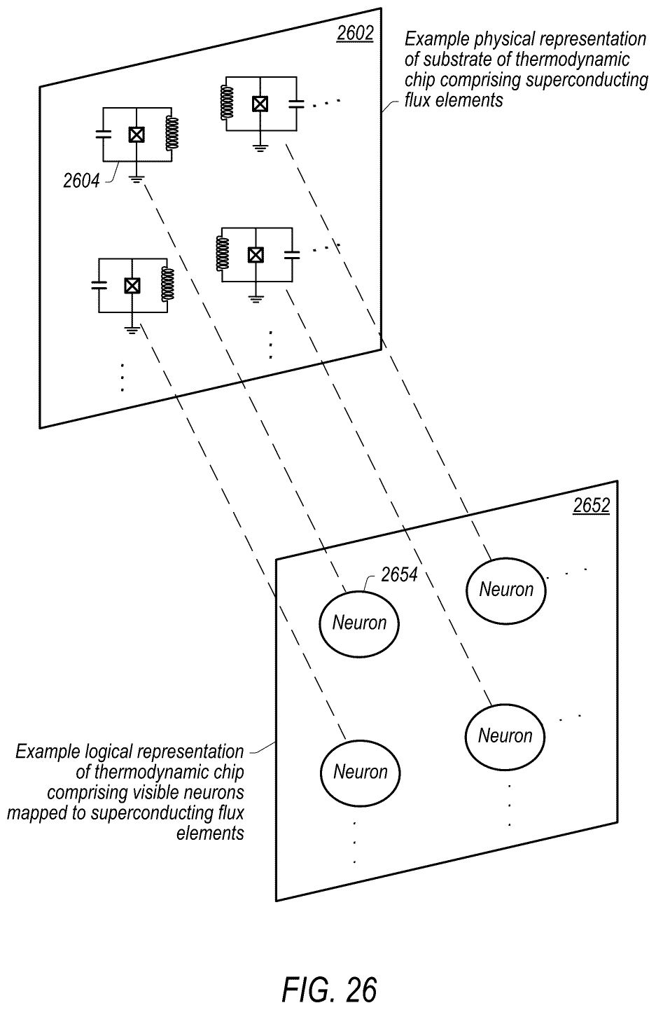

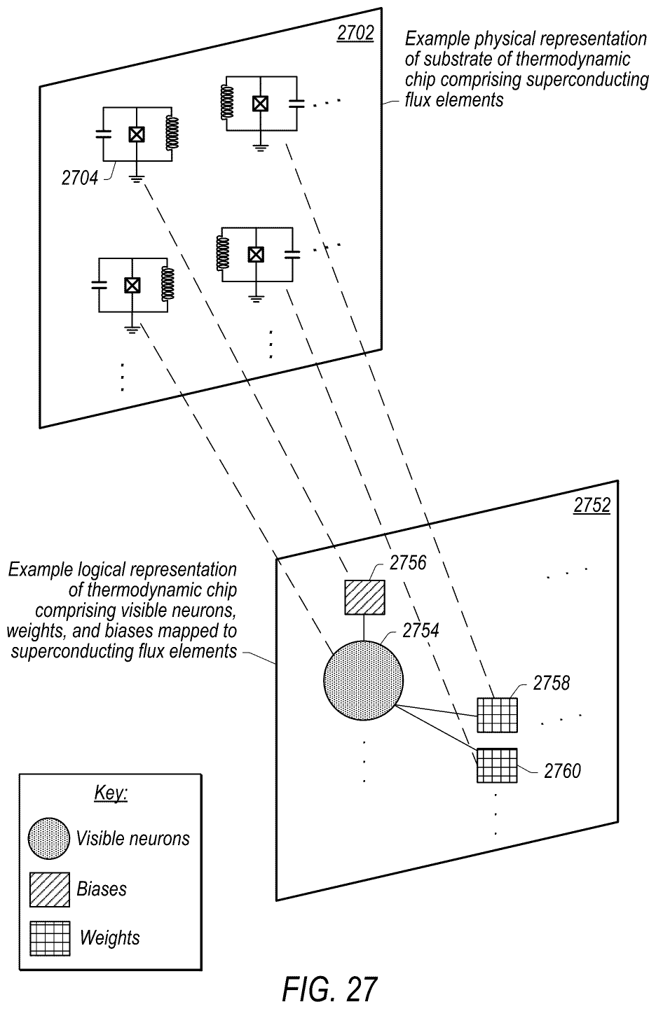

In some embodiments, each of the oscillators of the first energy-based model 100 and the second energy-based model 102, may be implemented using superconducting circuit elements, such as shown in FIG. 15A. These superconducting circuit elements may be used to implement oscillators that are mapped to visible or hidden neurons of the first or second energy-based model. Also, such oscillators may be mapped to synapses (e.g. weights or biases) of the first or second energy-based model. FIGS. 26-27 provide additional details regarding the mappings and hardware configurations used to implement example energy-based models. Also, as shown in FIG. 15A superconducting circuit elements may be used to implement the bias oscillator 118.

However, slightly different superconducting circuits may be used to implement the relay oscillator. For example, circuit 1502 shows an example implementation circuit for the relay oscillator 116, wherein the circuit 1502 implements a time-dependent frequency that can be controlled by controller 114. As another alternative, circuit 1504 shows an example implementation circuit for the relay oscillator 116, wherein the circuit 1504 implements a time-dependent mass that can be controlled by controller 114.

FIG. 15B is a diagram illustrating hardware components that may be used to implement oscillators of a first and second energy-based models (EBMs), as well as two different example hardware configurations of a relay oscillator that have a time-dependent mass or a time-dependent frequency, respectively, wherein the relay gadget does not include a bias oscillator, according to some embodiments.

Hardware components similar to FIG. 15A are shown, wherein respective relay gadgets do not include a respective bias oscillator, according to some embodiments.

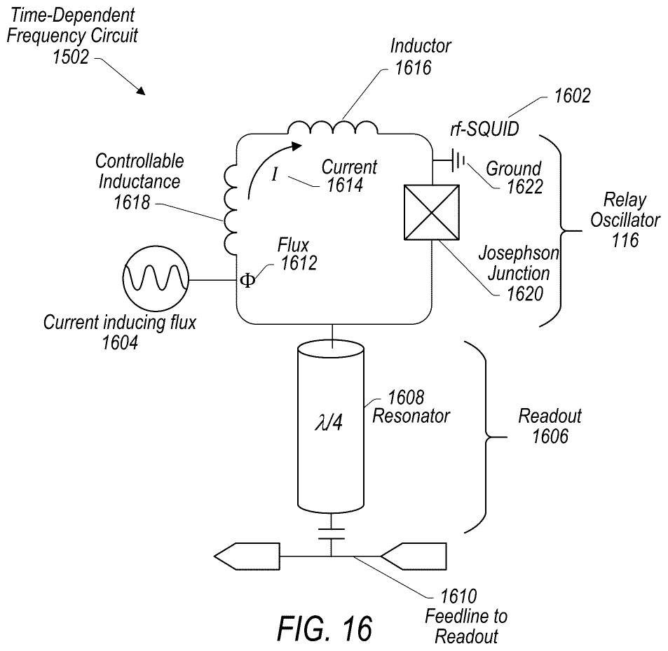

FIG. 16 is a diagram providing additional details regarding a hardware configuration used to implement a relay oscillator with a time-dependent frequency, according to some embodiments.

In some embodiments, a superconducting quantum interference device (SQUID) can be used in a circuit to implement a relay oscillator with time-dependent frequency along with a controllable current line that induces a flux in the circuit. For example, time-dependent frequency circuit 1502 includes rf-SQUID 1602 and current line 1604 that induces flux 1612. Note the added flux 1612 causes adjustments to the circuit flux 1618 and current 1614. The rf-SQUID 1602 and current inducing flux 1604 can be treated as a flux-tunable inductor, wherein changing the inductance of a LC-resonator changes the frequency of the time-dependent frequency circuit 1502. In order to make the frequency time-dependent, a time-dependent flux bias may be applied to a SQUID terminated resonator, such as shown in FIG. 16. In some embodiments, time-dependent frequency circuit 1602 also includes Josephson junction 1620 which is grounded 1622. In some embodiments, the Josephson junction 1620 and inductor 1616 (along with controllable inductor 1618) may form a part of relay oscillator 116. Note that in some embodiments relay oscillator 116 further includes a capacitor in parallel with the inductance and Josephson junction. However, for simplification purposes, the capacitor is not shown in FIG. 16.

In some embodiments, a value of the relay oscillator 116 may be read via readout 1606. For example, a position degree of freedom of the relay oscillator 116 may be readout via readout 1606. In some embodiments, readout 1606 includes a resonator 1608 which may have a length corresponding to ¼ the wavelength of the signal being readout from the relay oscillator 116. Also, readout 1606 may include feedline 1610.

Note that inducing the flux in the time-dependent frequency circuit 1502 via the current line 1604 and resulting induced flux 1612 allows for the Josephson inductance 1618 to be tuned. This inductance is in series with the resonator inductance 1616 so it simply adds to the L term of the LC oscillator. In the time-dependent frequency circuit 1502 shown in FIG. 16 there is a voltage antinode at the capacitor below the resonator 1608 and a voltage node at the SQUID end, which is grounded.

In some embodiments, the following function may be used for the time-dependent frequency:

$${ω}_{r} ( t ) = {ω}_{f}^{( r )} σ ( {k}_{r} ( t - {t}_{r} ) ) + {ω}_{r}$$

When a time-dependent frequency is used, the equation of motion for the average position of a relay oscillator (e.g. subscript r) between an oscillator (e.g. subscript y) and another oscillator (e.g. subscript x) becomes:

$${m}_{r} \frac{{d}^{2} {ϕ}_{r}}{{dt}^{2}} + γ {m}_{r} \frac{d {ϕ}_{r}}{dt} = - ( - 2 {λ}_{A} ( t ) ( {ϕ}_{y} - {ϕ}_{r} ) + {λ}_{B} ( t ) {ϕ}_{b} + {λ}_{X} ( t ) {ϕ}_{x} + {m}_{r} {ω}_{r}^{2} ( t ) {ϕ}_{r} ) + \sqrt{2 {m}_{r} ( t ) {k}_{B} T} \frac{{dW}_{t}^{( r )}}{dt} ,$$

$$or$$

$${m}_{r} \frac{{d}^{2} {ϕ}_{r}}{{dt}^{2}} + γ {m}_{r} \frac{d {ϕ}_{r}}{dt} = - ( - 2 {λ}_{A} ( t ) ( {ϕ}_{y} - {ϕ}_{r} ) - 2 {λ}_{B} ( t ) ( {ϕ}_{r} - {ϕ}_{b} ) + 2 {λ}_{X} ( t ) ( {ϕ}_{x} - {ϕ}_{r} ) + {m}_{r} {ω}_{r}^{2} ( t ) {ϕ}_{r} ) + \sqrt{2 {m}_{r} ( t ) {k}_{B} T} \frac{{dW}_{t}^{( r )}}{dt} .$$

Note that since frequency is a function of capacitance and inductance, e.g.

$$( ω = \frac{1}{\sqrt{LC}} ) ,$$

by adjusting the inductance (L), the frequency of the circuit can be controlled. For example, as discussed above, a SQUID can be treated as a flux-tunable inductor, and by changing the inductance of the flux-tunable inductor, the inductance of an LC resonator can be changed, which also changes the LC resonator's frequency. For example, a time dependent flux bias can be applied to a SQUID terminated resonator. Note that the above two equations of motion are for linear or quadratic coupling between the oscillators, furthermore, other couplings may also be used.

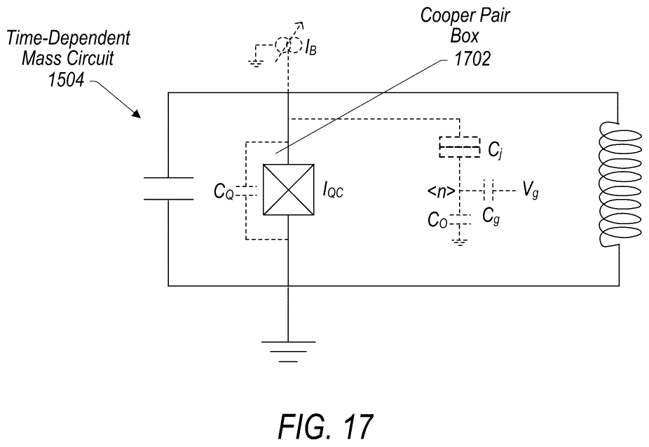

FIG. 17 is a diagram providing additional details regarding a hardware configuration used to implement a relay oscillator with a time-dependent mass, according to some embodiments.

A mass of an oscillator, is given by

$$m = {ϕ}_{0}^{2} C ,$$

where C is the capacitance of the circuit used to implement the oscillator and ϕ₀=h/2e is the reduced magnetic flux of the circuit used to implement the oscillator, e.g. a constant. Also, e is the elementary charge and h is Planck's constant. In some embodiments, a Cooper-pair box, such as Cooper-pair box 1702, may be used to change the capacitance of the circuit. This allows the oscillator mass to change as a function of time, in response to control signals from controller 114. The gate volage modulates the charge transfer through the small junction in the Cooper-pair box, thus leading to a gate-dependent capacitance.

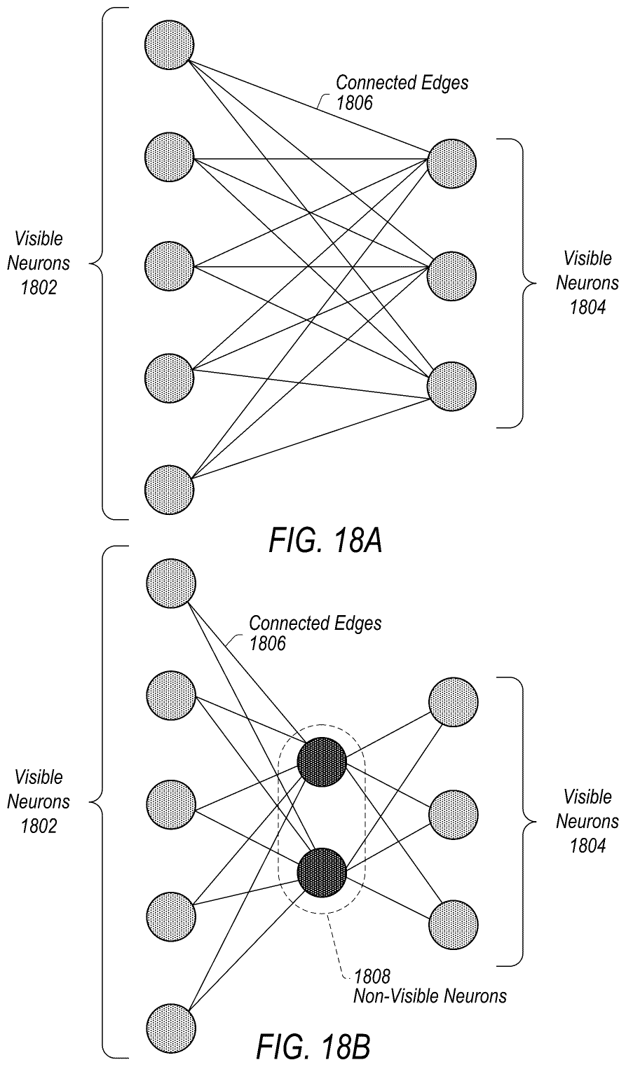

FIG. 18A illustrates example couplings between visible neurons of an energy-based model (EBM), according to some embodiments.

In some embodiments, input neurons and output neurons of an energy-based model, such as visible neurons 1802 and visible neurons 1804, may be directly linked via connected edges 1806. As shown in FIG. 18A, a given visible neuron 1802 of the five shown in the figure is connected, via edges 1806, to each of the respective three visible neurons 1804. A person having ordinary skill in the art should understand that FIG. 18A is meant to represent example embodiments of a graph architecture implemented using a thermodynamic chip that may be applied and that specific numbers of visible neurons 1802 and/or visible neurons 1804 shown in the figure are not meant to be restrictive. Additional configurations combining more/less visible neurons 1802 and/or visible neurons 1804 are also encompassed by the discussion herein. In addition, recall that neurons are logical representations of physical oscillators, such that, when describing neurons in FIGS. 18A and 18B, it should be understood that neurons and edges are implemented using oscillators and couplings.

FIG. 18B illustrates example couplings between visible neurons and non-visible neurons (e.g., hidden neurons) of an energy-based model (EBM), according to some embodiments.

In some embodiments, FIG. 18B may resemble additional example embodiments of an energy-based model architecture implemented using a thermodynamic chip. As shown in the figure, additional non-visible neurons 1808 may be used, which are respectively coupled, via edges 1806, to both visible neurons 1802 and to visible neurons 1804. Note that while the non-visible neurons are “not visible” from the perspective of inputs and outputs, the non-visible neurons may each correspond to a given oscillator. In addition, it may be noted that, in some embodiments that make use of non-visible neurons, no direct connections, via edges 1806, may be implemented between visible neurons 1802 and visible neurons 1804, but rather connections are routed firstly via non-visible neurons 1808, as shown in FIG. 18B. Sets of visible and non-visible neurons may be additionally referred to herein as “layers” of a given energy-based model architecture that is implemented using a thermodynamic chip, according to some embodiments. For example, visible neurons 1802 may be referred to as an input layer. Additionally, there may be one or more layers of non-visible neurons 1808.

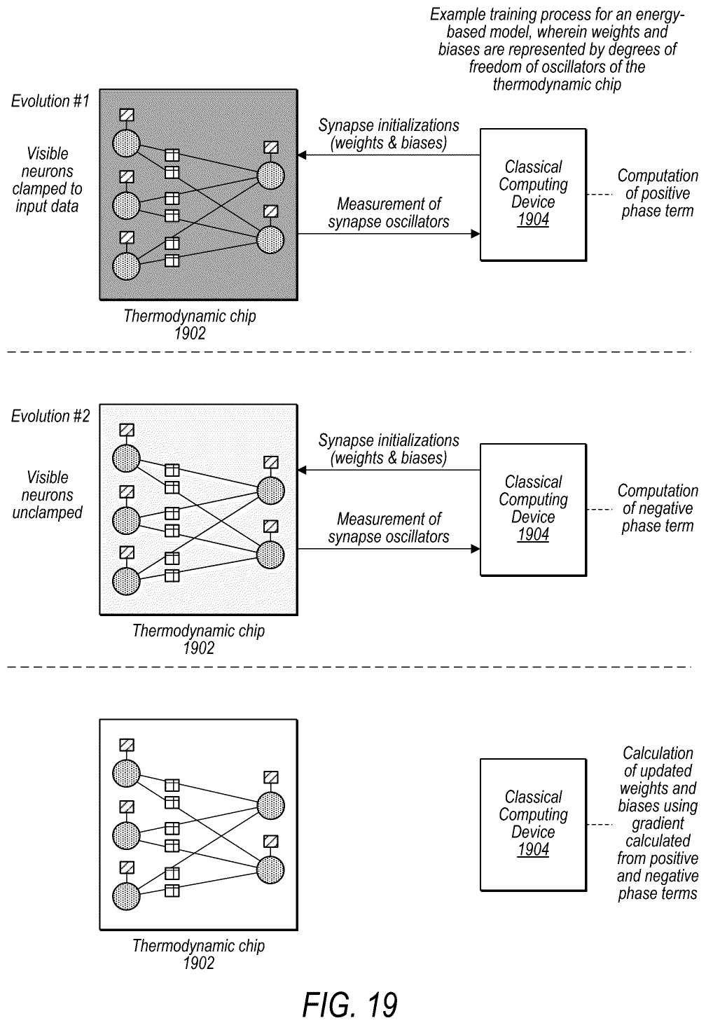

FIG. 19 is high-level diagram illustrating a process of determining weights and biases to be used in an energy-based model (EBM), wherein the weights and biases are determined using measurement values for synapse oscillators, according to some embodiments.

As shown in FIG. 19, in a first evolution, visible neurons of thermodynamic chip 1902 may be clamped to input data. For example, multiple mini-batches of input data may be clamped to visible neurons for multiple evolutions used to generate a first set of measurements used to compute a positive phase term. For example, the measurements may be used by classical computing device 1904 to compute the positive phase term.

Also, in a second (or other subsequent) evolution, the visible neurons may remain unclamped, such that the visible neuron oscillators are free to evolve along with the synapse oscillators during the second (or other subsequent) evolution. Measurements may also be taken and used by the classical computing device 1904 to compute a negative phase term.

Additionally, the positive and negative phase terms computed based on the first and second sets of measurements (e.g., clamped measurements and un-clamped measurements) may be used to calculate updated weights and biases.

This process may be repeated, with the determined updated weights and biases used as initial weights and biases for a subsequent iteration. In some embodiments, inferences generated using the updated weights and biases may be compared to training data to determine if the energy-based model has been sufficiently trained. If so, the model may transition into a mode of performing inferences using the learned weights and biases. If not sufficiently trained, the process may continue with additional iterations of determining updated weights and biases.

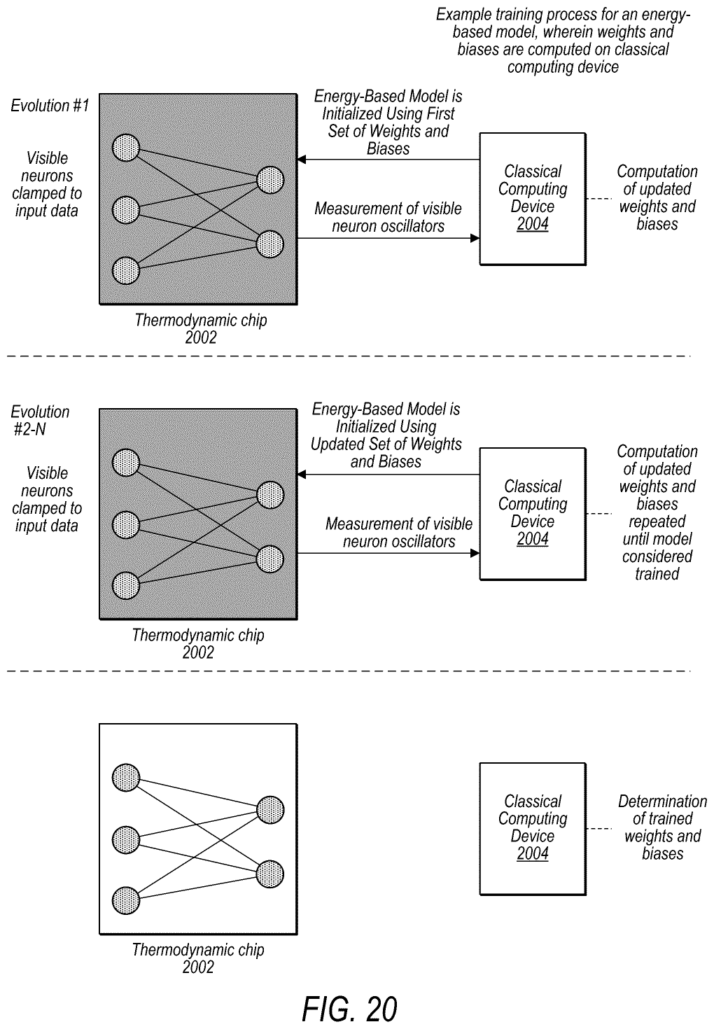

FIG. 20 is high-level diagram illustrating a process of determining weights and biases to be used in an energy-based model (EBM), wherein the weights and biases are computed using a classical computing device, according to some embodiments.

In some embodiments, updated weights and bias values may be computed iteratively by classical computing device 2004 based on inference measurements from thermodynamic chip 2002. For example, inference values may be compared to training data values, and new weights and biases may be iteratively computed until the inference values closely correspond to the training data. As can be seen in FIG. 20, in some embodiments the synapse oscillator may be omitted as degrees of freedom of the energy-based model. For example, when a classical computing device is used to iteratively determine the weight and bias values.

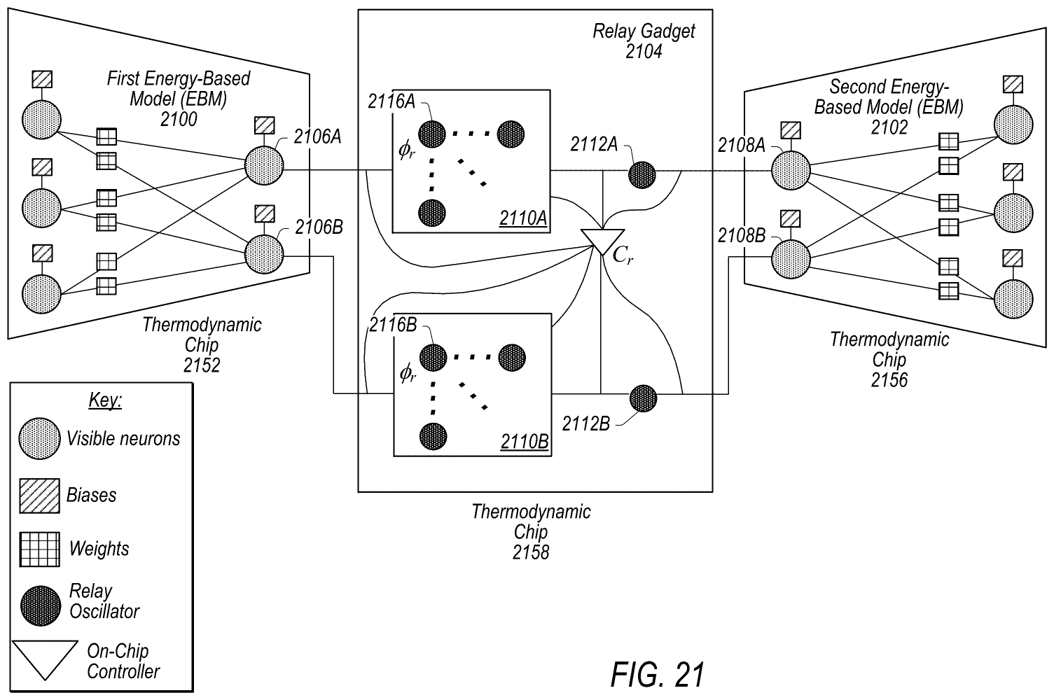

FIG. 21 illustrates an example configuration, wherein the first energy-based model (EBM), the second energy-based model (EBM) and the relay gadget are implemented using oscillators of different thermodynamic chips, according to some embodiments.

In some embodiments, a first energy-based model 2100, a second energy-based model 2102, and a relay gadget 2104 may be implemented at least in part on different thermodynamic chips. For example, in FIG. 21, energy-based model 2100 is implemented on thermodynamic chip 2152, energy-based model 2102 is implemented on thermodynamic chip 2156, and relay gadget 2104 is implemented on thermodynamic chip 2158. Another example configuration similar to FIG. 21 may include bias oscillators; however, the bias oscillators have been omitted in the figure for simplicity.

In some embodiments, the first energy-based model (EBM) 2100 may have two output oscillators 2106A and 2106B, wherein respective output oscillators may be connected to respective group of relay oscillators 2110A and 2110B. Furthermore, the group of relay oscillators 2110A and 2110B may be coupled to respective additional relay oscillators 2112A and 2112B, wherein additional relay oscillators 2112A and 2112B may be coupled to respective input oscillators 2108A and 2108B of the second energy-based model (EBM) 2102. One skilled in the art will recognize that an EBM configured with two output oscillators is not a limiting example, and a relay gadget may be configured to couple to one or more output oscillators and one or more input oscillators.

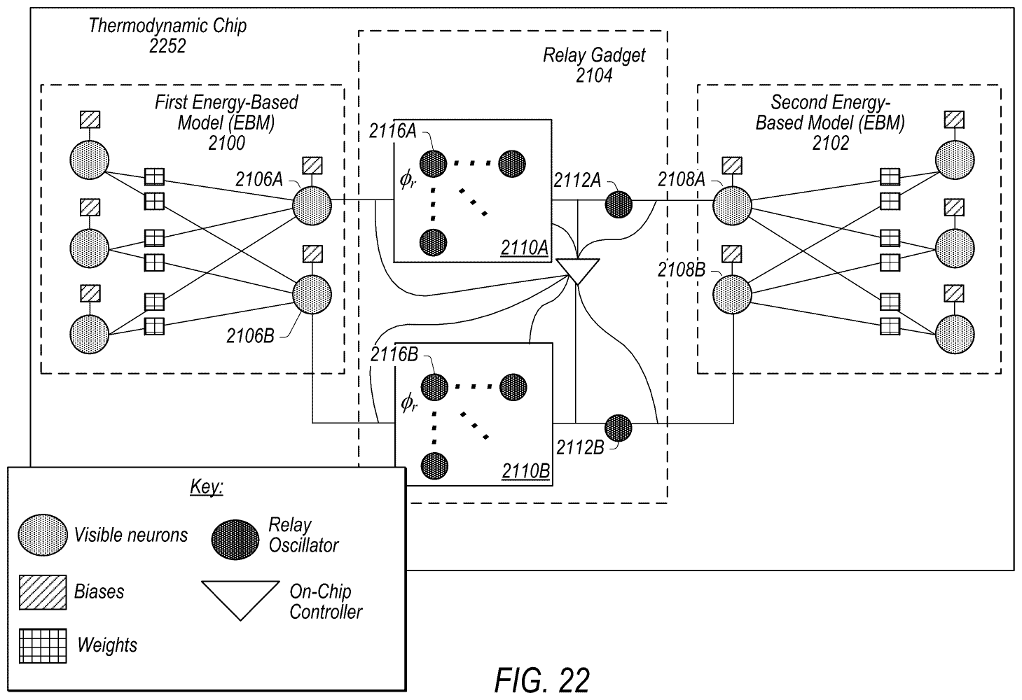

FIG. 22 illustrates an example configuration, wherein a first energy-based model (EBM), a second energy-based model (EBM) and a relay gadget are implemented using oscillators of a single thermodynamic chip, according to some embodiments.

In some embodiments multiple energy-based models and/or relay gadgets may be implemented using oscillators of a same thermodynamic chip. For example, in FIG. 22, a single thermodynamic chip 2252 implements energy-based model 2100, energy-based model 2102, and relay gadget 2104. Another example configuration may include bias oscillators; however, the bias oscillators have been omitted in this figure for simplicity.

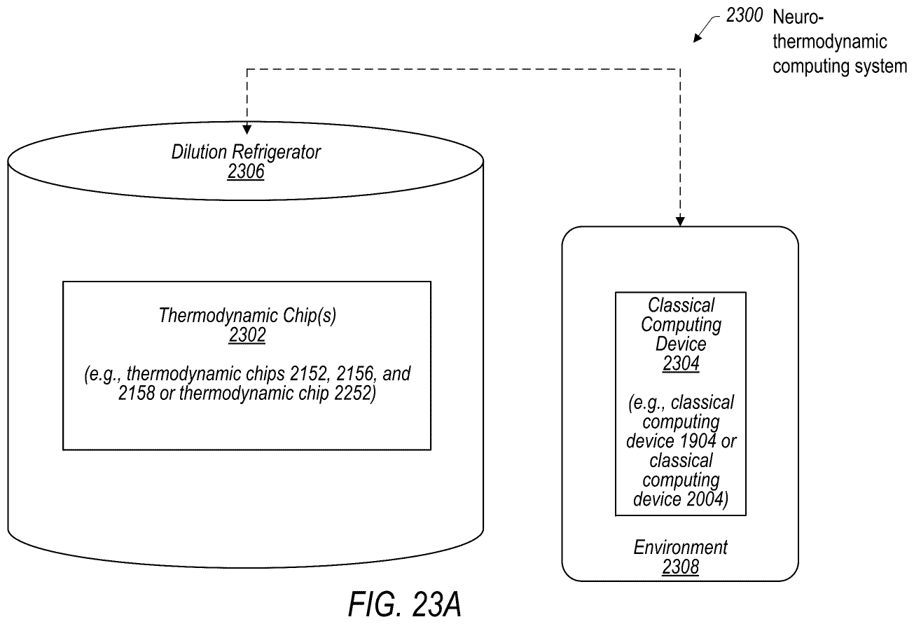

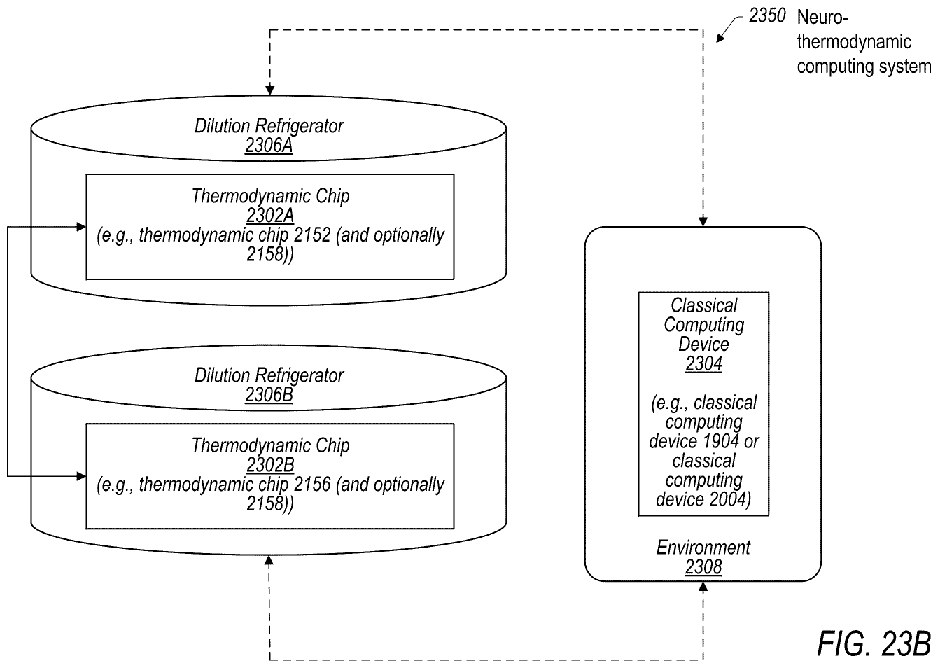

FIG. 23A is high-level diagram illustrating an example neuro-thermodynamic computer comprising a thermodynamic chip (e.g., that implements multiple energy-based models (EBMs) and a relay gadget) included in a dilution refrigerator and coupled to a classical computing device in an environment external to the dilution refrigerator, according to some embodiments.

In some embodiments, a neuro-thermodynamic computing system 2300 (as shown in FIG. 23A) may be used to implement the various embodiments shown in FIGS. 1-22 and may include one or more thermodynamic chip(s) 2302 placed in a dilution refrigerator 2306. In some embodiments, classical computing device 2304 may control temperature for dilution refrigerator 2306, and/or perform other tasks, such as helping to drive a pulse drive to change respective hyperparameters of the given system and/or perform measurements, such as those shown in FIGS. 1-22. Also, the classical computing device 2304 may perform other simple computing operations, such as are needed to determine updated weights and biases.

In some embodiments, classical computing device 2304 may include one or more devices such as a field-programmable gate array (FPGA), an application specific integrated circuit (ASIC), and/or other devices that may be configured to interact and/or interface with a thermodynamic chip within the architecture of neuro-thermodynamic computer 2300. For example, such devices may be used to tune hyperparameters of the given thermodynamic system, etc. as well as perform part of the calculations necessary to determine updated weights and biases. In some embodiments, the classical computing device 2304 may be placed in an environment 2308 outside of the dilution refrigerator 2306.

As shown in FIG. 23A, in embodiments where more than one thermodynamic chip is used with a relay gadget, multiple ones of the thermodynamic chips (e.g. thermodynamic chips 2152, 2156, and 2158 or thermodynamic chip 2252) and the relay gadget may be placed in the same dilution refrigerator 2306.

FIG. 23B is high-level diagram illustrating an example neuro-thermodynamic computer comprising multiple thermodynamic chips (e.g., that implement respective energy-based models (EBMs) and a relay gadget) included in multiple dilution refrigerators and coupled to a classical computing device in an environment external to the dilution refrigerators, according to some embodiments.

Also, in some embodiments, such as shown in FIG. 23B, a neuro-thermodynamic computing system 2350 may be implemented using multiple thermodynamic chips (e.g. thermodynamic chips 2302A (e.g. 2152 and optionally 2158) and 2302B (e.g. 2156 and optionally 2158)) that are placed in more than one dilution refrigerator (e.g. dilution refrigerators 2306A and 2306B).

24A is high-level diagram illustrating an example neuro-thermodynamic computer comprising a thermodynamic chip (e.g., that implements multiple energy-based models (EBMs) and a relay gadget) included in a dilution refrigerator and coupled to a classical computing device that is also included in the dilution refrigerator, according to some embodiments.

As another alternative, in some embodiments, a classical computing device used in a neuro-thermodynamic computer, such as in neuro-thermodynamic computer 2400, may be included in a dilution refrigerator with the thermodynamic chip. For example, neuro-thermodynamic computer 2400 includes both thermodynamic chip 2402 (e.g. thermodynamic chips 2152, 2156, and 2158 or thermodynamic chip 2252) and classical computing device 2404 in dilution refrigerator 2406.

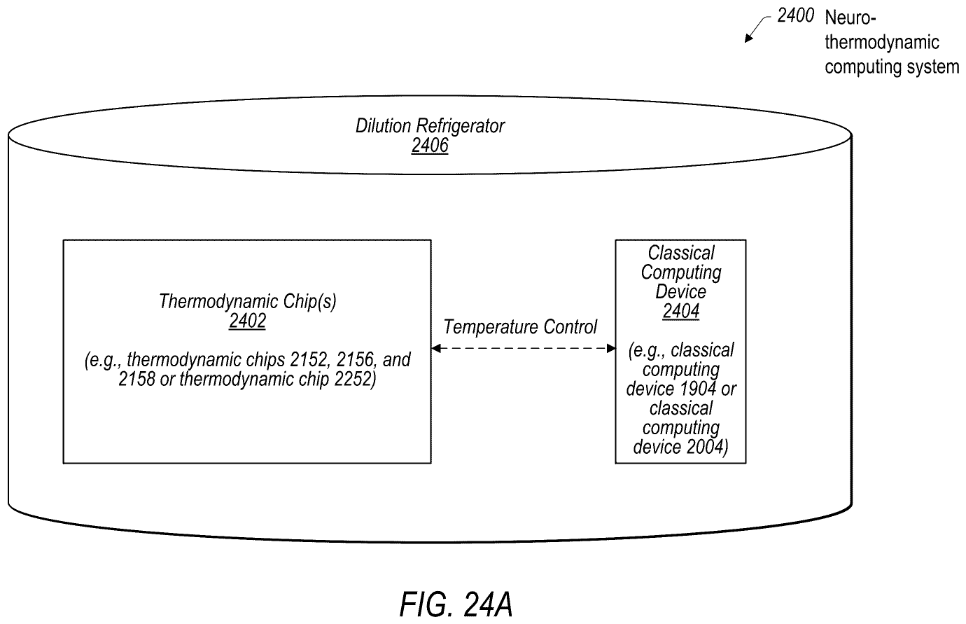

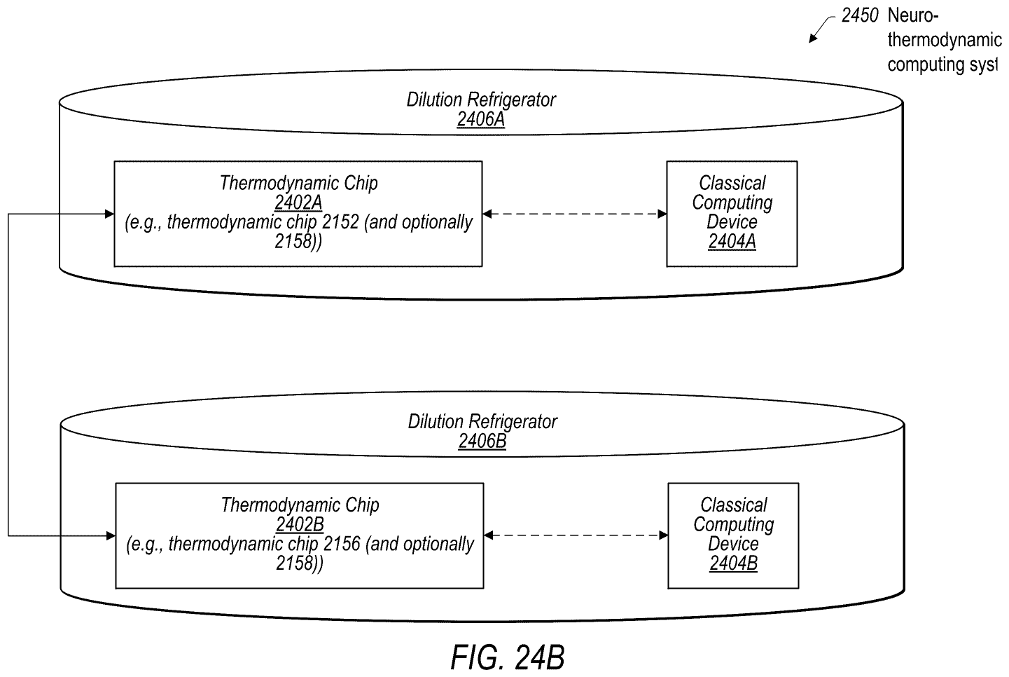

FIG. 24B is high-level diagram illustrating an example neuro-thermodynamic computer comprising multiple thermodynamic chips (e.g., that implement respective energy-based models (EBMs) and a relay gadget) included in respective dilution refrigerators and coupled to respective classical computing devices that are also included in the respective dilution refrigerators, according to some embodiments.

Also, in some embodiments, a similar configuration as shown in FIG. 23A may be used, however the thermodynamic chips may be included in more than one dilution refrigerator. For example, thermodynamic chips 2402A (e.g. 2152 and optionally 2158) and 2402B (e.g. 2156 and optionally 2158) may be included in dilution refrigerators 2406A and 2406B, respectively.

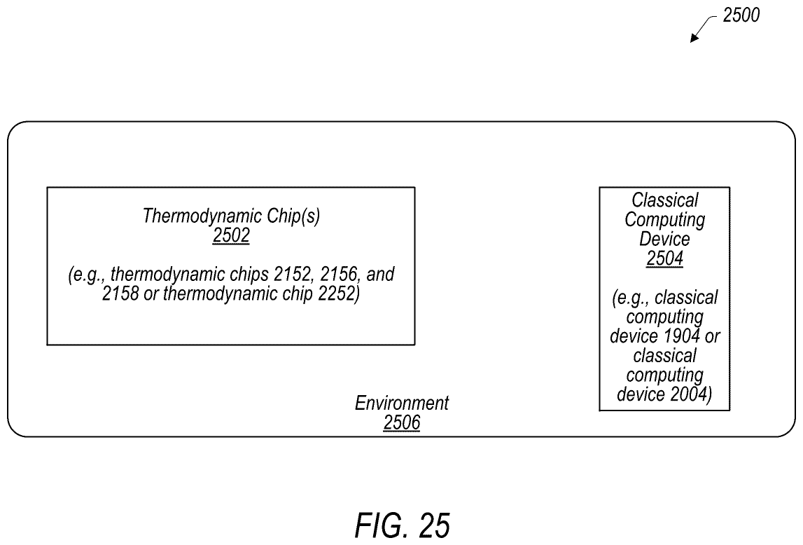

FIG. 25 is high-level diagram illustrating an example neuro-thermodynamic computer comprising one or more thermodynamic chips (e.g., that implement respective energy-based models (EBMs) and a relay gadget) coupled to a classical computing device in an environment other than a dilution refrigerator, according to some embodiments.

Also, in some embodiments, a neuro-thermodynamic computer, such as neuro-thermodynamic computer 2500, may be implemented in an environment other than a dilution refrigerator. For example, neuro-thermodynamic computer 2500 includes thermodynamic chip(s) 2502 (e.g. 2152, 2156, and 2158 or 2158) and classical computing device 2504, in environment 2506. In some embodiments, environment 2506 may be temperature controlled and, the classical computing device (or other device) may control the temperature of environment 2506 in order to achieve a given level of evolution according to Langevin dynamics.

FIG. 26 is a high-level diagram illustrating oscillators included in a substrate of a thermodynamic chip and mapping of the oscillators to logical neurons of the thermodynamic chip, according to some embodiments.

In some embodiments, a substrate 2602 may be included in a thermodynamic chip, such as any one of the thermodynamic chips described above. Oscillators 2604 of substrate 2602 may be mapped in a logical representation 2652 to neurons 2654, as well as weights and biases (shown in FIG. 27). In some embodiments, oscillators 2604 may include oscillators with potentials ranging from a single well potential to a multi-well potential (see FIGS. 9A and 9B) and may be mapped to other neurons, weights, and biases.

In some embodiments, Josephson junctions and/or superconducting quantum interference devices (SQUIDS) may be used to implement and/or excite/control the oscillators 2604. In some embodiments, the oscillators 2604 may be implemented using superconducting flux elements (e.g., qubits). In some embodiments, the superconducting flux elements may physically be instantiated using a superconducting circuit built out of coupled nodes comprising capacitive, inductive, and Josephson junction elements, connected in series or parallel, such as shown in FIG. 26 for oscillator 2604. However, in some embodiments, generally speaking various non-linear flux loops may be used to implement the oscillators 2604, such as those having single-well potential, double-well potential, or various other potentials, such as a potential somewhere between a single-well potential and a double-well potential (see FIGS. 9A and 9B).

FIG. 27 is an additional high-level diagram illustrating oscillators included in a substrate of a thermodynamic chip mapped to logical neurons, weights, and biases of a given neuro-thermodynamic computing system, according to some embodiments.

While weights and biases are not shown in FIG. 26 for ease of illustration, respective ones of the visible neurons 2654 of FIG. 26 may each have an associated bias, and edges connecting the neurons 2654 may have associated weights. For example, FIGS. 19-22 illustrate an arrangement of five visible neurons along with associated weights and biases. Each of the weights and biases may be mapped to oscillators in the thermodynamic chip, as well as the visible (and non-visible) neurons being mapped to oscillators in the thermodynamic chip. For example, FIG. 27 shows a portion of a thermodynamic chip, wherein weights and biases associated with a given neuron 2754 are shown. For example, bias 2756 may be a bias value for visible neuron 2754 and weights 2758 and 2760 may be weights for edges formed between visible neuron 2754 and other visible neurons of the thermodynamic chip. As shown in FIG. 27, each of the chip elements (visible neuron 2754, bias 2756, weight 2758, and weight 2760) may be mapped to separate ones of oscillators 2704. This may allow the visible neurons (and/or hidden neurons), weights, and biases to have independent degrees of freedom within a given thermodynamic chip that can separately evolve.

In some embodiments, oscillators associated with weights and biases, such as bias 2756 and weights 2758 and 2760, may be allowed to evolve during a training phase and may be held nearly constant during an inference phase. For example, in some embodiments, larger “masses” may be used for the weights and biases such that the weights and biases evolve more slowly than the visible neurons. This may have the effect of holding the weight values and the bias values nearly constant during an evolution phase used for generating inference values.

### Illustrative Computer System

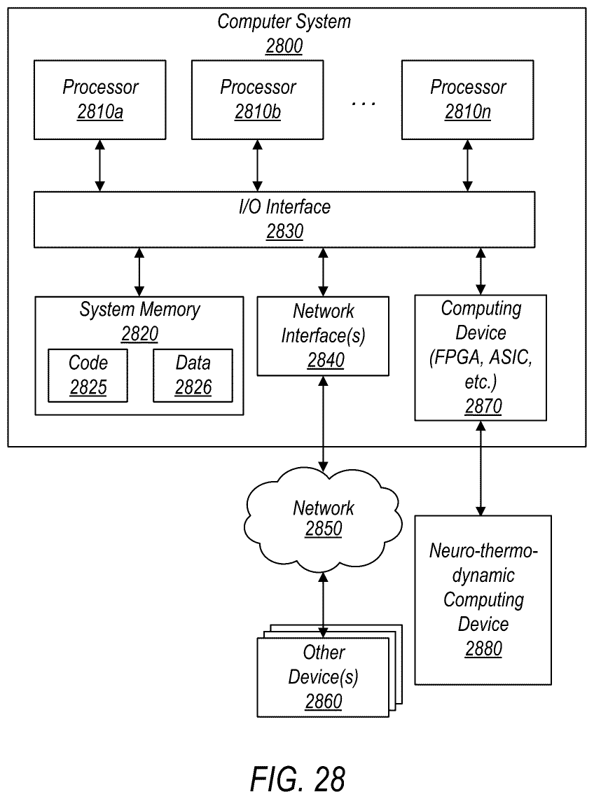

FIG. 28 is a block diagram illustrating an example computer system that may be used in at least some embodiments. In some embodiments, the computing system shown in FIG. 28 may be used, at least in part, to implement any of the techniques described above in FIGS. 1-27. Furthermore, computer system 2800 may be configured to interact and/or interface with neuro-thermodynamic computing device 2880, according to some embodiments.

In the illustrated embodiment, computer system 2800 includes one or more processors 2810 coupled to a system memory 2820 (which may comprise both non-volatile and volatile memory modules) via an input/output (I/O) interface 2830. Computer system 2800 further includes a network interface 2840 coupled to I/O interface 2830. Classical computing functions may be performed on a classical computer system, such as computing computer system 2800.

Additionally, computer system 2800 includes computing device 2870 coupled to thermodynamic chip 2880. In some embodiments, computing device 2870 may be a field programmable gate array (FPGA), application specific integrated circuit (ASIC) or other suitable processing unit. In some embodiments, computing device 2870 may be a similar computing device as described in FIGS. 1-27, such as classical computing devices used to control a thermodynamic chip. In some embodiments, neuro thermodynamic computing device 2880 may be a similar neuro thermodynamic computing device as described in FIGS. 1-27, such as neuro thermodynamic computing devices implemented using thermodynamic chips.

In various embodiments, computer system 2800 may be a uniprocessor system including one processor 2810, or a multiprocessor system including several processors 2810 (e.g., two, four, eight, or another suitable number). Processors 2810 may be any suitable processors capable of executing instructions. For example, in various embodiments, processors 2810 may be general-purpose or embedded processors implementing any of a variety of instruction set architectures (ISAs), such as the x86, PowerPC, SPARC, or MIPS ISAs, or any other suitable ISA. In multiprocessor systems, each of processors 2810 may commonly, but not necessarily, implement the same ISA. In some implementations, graphics processing units (GPUs) may be used instead of, or in addition to, conventional processors.

System memory 2820 may be configured to store instructions and data accessible by processor(s) 2810. In at least some embodiments, the system memory 2820 may comprise both volatile and non-volatile portions; in other embodiments, only volatile memory may be used. In various embodiments, the volatile portion of system memory 2820 may be implemented using any suitable memory technology, such as static random-access memory (SRAM), synchronous dynamic RAM or any other type of memory. For the non-volatile portion of system memory (which may comprise one or more NVDIMMs, for example), in some embodiments flash-based memory devices, including NAND-flash devices, may be used. In at least some embodiments, the non-volatile portion of the system memory may include a power source, such as a supercapacitor or other power storage device (e.g., a battery). In various embodiments, memristor based resistive random-access memory (ReRAM), three-dimensional NAND technologies, Ferroelectric RAM, magneto resistive RAM (MRAM), or any of various types of phase change memory (PCM) may be used at least for the non-volatile portion of system memory. In the illustrated embodiment, program instructions and data implementing one or more desired functions, such as those methods, techniques, and data described above, are shown stored within system memory 2820 as code 2825 and data 2826.

In some embodiments, I/O interface 2830 may be configured to coordinate I/O traffic between processor 2810, system memory 2820, computing device 2870, and any peripheral devices in the computer system, including network interface 2840 or other peripheral interfaces such as various types of persistent and/or volatile storage devices. In some embodiments, I/O interface 2830 may perform any necessary protocol, timing or other data transformations to convert data signals from one component (e.g., system memory 2820) into a format suitable for use by another component (e.g., processor 2810). In some embodiments, I/O interface 2830 may include support for devices attached through various types of peripheral buses, such as a variant of the Peripheral Component Interconnect (PCI) bus standard or the Universal Serial Bus (USB) standard, for example. In some embodiments, the function of I/O interface 2830 may be split into two or more separate components, such as a north bridge and a south bridge, for example. Also, in some embodiments some or all of the functionality of I/O interface 2830, such as an interface to system memory 2820, may be incorporated directly into processor 2810.

Network interface 2840 may be configured to allow data to be exchanged between computing device 2800 and other devices 2860 attached to a network or networks 2850, such as other computer systems or devices. In various embodiments, network interface 2840 may support communication via any suitable wired or wireless general data networks, such as types of Ethernet network, for example. Additionally, network interface 2840 may support communication via telecommunications/telephony networks such as analog voice networks or digital fiber communications networks, via storage area networks such as Fibre Channel SANs, or via any other suitable type of network and/or protocol.

In some embodiments, system memory 2820 may represent one embodiment of a computer-accessible medium configured to store at least a subset of program instructions and data used for implementing the methods and apparatus discussed in the context of FIG. 1 through FIG. 27. However, in other embodiments, program instructions and/or data may be received, sent or stored upon different types of computer-accessible media. Generally speaking, a computer-accessible medium may include non-transitory storage media or memory media such as magnetic or optical media, e.g., disk or DVD/CD coupled to computer system 2800 via I/O interface 2830. A non-transitory computer-accessible storage medium may also include any volatile or non-volatile media such as RAM (e.g., SDRAM, DDR SDRAM, RDRAM, SRAM, etc.), ROM, etc., that may be included in some embodiments of computer system 2800 as system memory 2820 or another type of memory. In some embodiments, a plurality of non-transitory computer-readable storage media may collectively store program instructions that when executed on or across one or more processors implement at least a subset of the methods and techniques described above. A computer-accessible medium may further include transmission media or signals such as electrical, electromagnetic, or digital signals, conveyed via a communication medium such as a network and/or a wireless link, such as may be implemented via network interface 2840. Portions or all of multiple computing devices such as that illustrated in FIG. 28 may be used to implement the described functionality in various embodiments; for example, software components running on a variety of different devices and servers may collaborate to provide the functionality. In some embodiments, portions of the described functionality may be implemented using storage devices, network devices, or special-purpose computer systems, in addition to or instead of being implemented using general-purpose computer systems. The term “computer system”, as used herein, refers to at least all these types of devices, and is not limited to these types of devices.

### CONCLUSION

Various embodiments may further include receiving, sending or storing instructions and/or data implemented in accordance with the foregoing description upon a computer-accessible medium. Generally speaking, a computer-accessible medium may include storage media or memory media such as magnetic or optical media, e.g., disk or DVD/CD-ROM, volatile or non-volatile media such as RAM (e.g., SDRAM, DDR, RDRAM, SRAM, etc.), ROM, etc., as well as transmission media or signals such as electrical, electromagnetic, or digital signals, conveyed via a communication medium such as network and/or a wireless link.

The various methods as illustrated in the Figures above and the Appendix below and described herein represent exemplary embodiments of methods. The methods may be implemented in software, hardware, or a combination thereof. The order of method may be changed, and various elements may be added, reordered, combined, omitted, modified, etc.

It will also be understood that, although the terms first, second, etc., may be used herein to describe various elements, these elements should not be limited by these terms. These terms are only used to distinguish one element from another. For example, a first contact could be termed a second contact, and, similarly, a second contact could be termed a first contact, without departing from the scope of the present invention. The first contact and the second contact are both contacts, but they are not the same contact.

Various modifications and changes may be made as would be obvious to a person skilled in the art having the benefit of this disclosure. It is intended to embrace all such modifications and changes and, accordingly, the above description and the Appendix below is to be regarded in an illustrative rather than a restrictive sense.

What is claimed is:

1. A system comprising:
one or more thermodynamic chips, wherein the one or more thermodynamic chips comprise:
an output oscillator, an input oscillator, and a set of relay oscillators configured to implement a relay gadget for relaying information between the output oscillator and the input oscillator, wherein the set of relay oscillators configured to implement the relay gadget comprises:
a group of one or more relay oscillators; and
an additional relay oscillator; and
an on-chip classical controller configured to:
cause a first set of one or more pulses to be emitted, wherein the first set of pulses cause one or more relay oscillators of the group of relay oscillators to be coupled to the output oscillator;
cause a second set of one or more pulses to be emitted, wherein the second set of pulses cause one or more relay oscillators of the group of relay oscillators to be coupled to the additional relay oscillator; and
cause a third set of one or more pulses to be emitted, wherein the third set of pulses cause the additional relay oscillator to be coupled to the input oscillator.

2. The system of claim 1, wherein:
one or more couplings between the additional relay oscillator and the one or more relay oscillators of the group of relay oscillators causes the additional relay oscillator to represent an expectation value of the output oscillator based at least in part on one or more sample values of the output oscillator received by at least one of the one or more relay oscillators in the group of relay oscillators; and
another coupling between the additional relay oscillator and the input oscillator causes the expectation value to be transferred to the input oscillator.

3. The system of claim 2, wherein:
the group of relay oscillators comprises a plurality of relay oscillators, wherein respective ones of the relay oscillators of the group of relay oscillators are configured to store respective sample values of the output oscillator based at least in part on respective couplings between the respective ones of the relay oscillators of the group of relay oscillators and the output oscillator; and
the on-chip classical controller is further configured to cause another set of one or more pulses to be emitted, wherein the other set of pulses:
turns off the respective couplings between the output oscillator and the respective ones of the relay oscillator of the group of relay oscillators at different times; and
wherein turning off the coupling causes the respective ones of the relay oscillators of the group of relay oscillators to store respective samples.

4. The system of claim 2, wherein:
the group of relay oscillators comprises a single relay oscillator, wherein the single relay oscillator is configured to store a respective sample value of the output oscillator one at a time based at least in part on a coupling between the single relay oscillator with the output oscillator; and
the on-chip classical controller is further configured to cause the first set of one or more pulses and the second set of one or more pulses to be emitted in a sequential pulse sequence, wherein repeatedly emitting the first and second sets of pulses in the pulse sequence causes a position of the additional relay oscillator to be incrementally adjusted.

5. The system of claim 2, wherein the group of relay oscillators comprises a plurality of relay oscillators arranged in series, and wherein the plurality of relay oscillators arranged in series is further arranged with incrementally increasing respective products of mass and frequency squared for the respective relay oscillators arranged in series.

6. The system of claim 2, wherein a distribution of the one or more sample values of the output oscillator correspond to a potential of the output oscillator.

7. The system of claim 2, wherein propagation from the output oscillator to the input oscillator via the relay oscillators is forwards and backwards compatible.

8. A thermodynamic relay gadget, comprising:
a group of one or more relay oscillators;
an additional relay oscillator; and
a controller configured to:
cause a first set of one or more pulses to be emitted, wherein the first set of pulses cause one or more relay oscillators of the group of relay oscillators to be coupled to an output oscillator;
cause a second set of one or more pulses to be emitted, wherein the second set of pulses cause one or more relay oscillators of the group of relay oscillators to be coupled to the additional relay oscillator; and
cause a third set of one or more pulses to be emitted, wherein the third set of pulses cause the additional relay oscillator to be coupled to an input oscillator.

9. The gadget of claim 8, wherein:
one or more couplings between the additional relay oscillator and the one or more relay oscillators of the group of relay oscillators causes the additional relay oscillator to represent an expectation value of the output oscillator based at least in part on one or more sample values of the output oscillator received by at least one of the one or more relay oscillators in the group of relay oscillators; and
another coupling between the additional relay oscillator and the input oscillator causes the expectation value to be transferred to the input oscillator.

10. The gadget of claim 9, wherein:
the group of relay oscillators comprises a plurality of relay oscillators, wherein respective ones of the relay oscillators of the group of relay oscillators are configured to store one of the sample values of the output oscillator based at least in part on respective couplings between the respective ones of the relay oscillators of the group of relay oscillators and the output oscillator; and
the on-chip classical controller is further configured to cause another set of one or more pulses to be emitted, wherein the other set of pulses:
turns off the respective couplings between the output oscillator and the respective ones of the relay oscillator of the group of relay oscillators at different times; and
causes the respective ones of the relay oscillators of the group of relay oscillators to store respective samples.

11. The gadget of claim 9 wherein:
the group of relay oscillators comprises a single relay oscillator, wherein the single relay oscillator is configured to store one sample value of the output oscillator at a time based at least in part on a coupling between the single relay oscillator with the output oscillator; and
the on-chip classical controller is further configured to cause the first set of one or more pulses and the second set of one or more pulses to be emitted in a sequential pulse sequence, wherein repeatedly emitting the first and second sets of pulses in the pulse sequence causes a position of the additional relay oscillator to be incrementally adjusted.

12. The gadget of claim 9, wherein the group of relay oscillators comprises a plurality of relay oscillators arranged in series, and wherein the plurality of relay oscillators arranged in series is further arranged with incrementally increasing respective products of mass and frequency squared for the respective relay oscillators arranged in series.

13. The gadget of claim 9, wherein a distribution of the one or more sample values of the output oscillator correspond to a potential of the output oscillator.

14. The gadget of claim 9, wherein propagation from the output oscillator to the input oscillator via the relay oscillators is forwards and backwards compatible.

15. A controller, comprising:
processing circuitry configured to:
cause a first set of one or more pulses to be emitted, wherein the first set of pulses cause one or more relay oscillators of the group of relay oscillators to be coupled to an output oscillator;
cause a second set of one or more pulses to be emitted, wherein the second set of pulses cause one or more relay oscillators of the group of relay oscillators to be coupled to an additional relay oscillator; and
cause a third set of one or more pulses to be emitted, wherein the third set of pulses cause the additional relay oscillator to be coupled to an input oscillator.

16. The controller of claim 15, wherein:
one or more couplings between the additional relay oscillator and the one or more relay oscillators of the group of relay oscillators, resulting from the second set of pulses, causes the additional relay oscillator to represent an expectation value of the output oscillator based at least in part on one or more sample values of the output oscillator received by at least one of the one or more relay oscillators in the group of relay oscillators; and
another coupling between the additional relay oscillator and the input oscillator, resulting from the third set of pulses, causes the expectation value to be transferred to the input oscillator.

17. The controller of claim 16, wherein the on-chip classical controller is further configured to cause another set of one or more pulses to be emitted, wherein the other set of pulses turns off respective couplings between the output oscillator and respective ones of the relay oscillator of the group of relay oscillators at different times, wherein turning off the coupling causes the respective ones of the relay oscillators of the group of relay oscillators store respective samples.

18. The controller of claim 16, wherein the on-chip classical controller is further configured to cause the first set of one or more pulses and the second set of one or more pulses to be emitted in a sequential pulse sequence, wherein repeatedly emitting the first and second sets of pulses in the pulse sequence causes a position of the additional relay oscillator be incrementally adjusted.

19. The controller of claim 16, wherein the group of relay oscillators comprises a plurality of relay oscillators arranged in series, and wherein the plurality of relay oscillators arranged in series is further arranged with incrementally increasing respective products of mass and frequency squared for the respective relay oscillators arranged in series.

20. The controller of claim 16, wherein the controller is configured to adjust the mass or frequencies of the relay oscillators.

21. A thermodynamic relay gadget, comprising:
a relay oscillator; and
a controller configured to:
cause a first set of one or more pulses to be emitted to couple the relay oscillator to a first oscillator;
cause one or more control signals to be emitted to tune a product of mass times frequency squared of the relay oscillator;
cause another set of one or more pulses to be emitted to couple the relay oscillator to a second oscillator,
wherein the relay oscillator is configured to relay an expectation value from the first oscillator to the second oscillator.

22. The thermodynamic relay gadget of claim 21 wherein the controller is further configured to tune a product of mass and frequency squared of the relay oscillator, wherein the product of mass and frequency squared of the relay oscillator is smaller than a product of mass and frequency squared of the first oscillator when the relay oscillator is coupled to the first oscillator.

23. The thermodynamic relay gadget of claim 22, wherein the controller is configured to tune the product of mass and frequency squared of the relay oscillator to be larger than a product of mass and frequency squared of the second oscillator when the relay oscillator is coupled to the second oscillator.
